(19) United States
(12) Patent Application Publication
(10) Pub. No.: US 2002/0051926 A1
(43) Pub. Date: May 2, 2002

(54) Cyanine-based organic dyes, photopolymerizable compositions, and recording materials

(76) Inventors: Masanobu Takashima, Shizuoka-ken (JP); Yuuichi Fukushige, Shizuoka-ken (JP)

Correspondence Address: SUGHRUE, MION, ZINN, MACPEAK & SEAS, PLLC, Suite 800, 2100 Pennsylvania Avenue, N.W., Washington, DC, 20037-3213, US

(21) Appl. No.: 09/781,410

(22) Filed: Feb. 13, 2001

(30) Foreign Application Priority Data
Feb. 14, 2000 (JP) 2000-34935

(51) Int. Cl. G03F 7/029; G03F 7/26

(52) U.S. Cl. 430/138; 430/2; 430/7; 430/302; 430/281.1

(57) ABSTRACT

A novel cyanine-based dye, a photopolymerizable composition having high sensitivity not only to ultraviolet light but also to visible-to-infrared light, and a recording material which is excellent in sensitivity and decolorization in background and which can form sharp, high-contrast images. The cyanine-based dye is an organic dye represented by the following general formula (3). The photopolymerizable composition contains a polymerizable compound having an ethylenically unsaturated bond, a compound represented by the following general formula (1), and a radical generator capable of generating a radical by interacting with that compound:

[chemical structure]

### BACKGROUND OF THE INVENTION

1. Field of the Invention

The present invention relates to novel organic dyes, novel photopolymerizable compositions, and recording materials. More specifically, the present invention relates to cyanine-based organic dyes excellent in decolorization property, photopolymerizable compositions and recording materials which can be used in wide range of fields including inks, color filters, holograms, proofs, sealants, adhesives, planographic printing, resin relief plates, and photoresists.

2. Description of the Related Art

A photopolymerizable composition basically contains a photopolymerization initiator and a compound containing in the molecule thereof two or more ethylenically unsaturated bonds and being capable of addition polymerization (this compound is hereinafter referred to as a “polyfunctional monomer”). The photopolymerizable composition hardens when irradiated with light so that its adhesiveness changes or it becomes insoluble in a solvent. By using these properties, the photopolymerizable composition is utilized in a wide range of fields including photography, printing, metal surface processing, and inks. Functions and examples of application of photopolymerizable compositions are described in many common books.

For example, details are described in J. Kosar, “Light Sensitive Systems” (J. Wiley & Sons, New York, 1965, pp.158-193), and K. I. Jacobson, R. E. Jacobson, “Imaging Systems” (J. Wiley & Sons, New York, 1976, pp.181-222) and the like.

In recent years, as an imaging method using a photopolymerizable composition, an imaging system utilizing photosensitive microcapsules, which enclose the photopolymerizable composition, has been proposed. For example, Japanese Patent Application Laid-Open (JPA) Nos. 57-124343, 57-179836, and 57-197538 disclose dye image formation wherein a color-forming sheet, which has a coating layer containing a photopolymerizable composition composed of a vinyl compound and a photopolymerization initiator and microcapsules enclosing dye, is exposed to light, and thereafter put together face to face with an image-receiving sheet such that pressure is applied to the entire sheet.

Further, JP-A Nos. 3-87827 and 4-211252 disclose photo- and heat-sensitive color-forming recording materials containing two components wherein one of the two component is enclosed in microcapsules and the other constitutes the hardenable compound of the photo-hardenable composition or is present together with the photo-hardenable composition outside the microcapsules. Disclosed as an example of the latter recording material is a photo- and heat-sensitive color-forming recording material having a layer which contains microcapsules enclosing an electron-donating colorless dye and, outside the microcapsules, a photo-hardenable composition containing an electron-accepting compound, a polymerizable vinyl monomer, and a photopolymerization initiator.

The recording materials utilizing the above-described polymerizable compositions are environmentally very desirable because image recording is possible in a perfectly dry system without using a developing solution, and therefore no waste is produced.

If the light to be used when images are recorded with the photosensitive recording materials is not limited to UV light and shortwave visible light, inexpensive infrared laser or blue-to-red light can also be used. Thus, recording can be advantageously performed by use of such inexpensive light. However, although the recording materials utilizing the photopolymerizable compositions are sensitive to ultraviolet light, many of these materials are not sensitive to visible-or-infrared light. Even when the material is sensitive, the sensitivity is often insufficient. As a result, in some cases, images formed are not sharp or the contrast between image portions and non-image portions is low. Therefore, a need exists for a recording material having a higher sensitivity.

Generally, a spectral sensitizing dye is used to increase sensitivity to the light to be used for image recording (writing) in these recording materials. Therefore, it is a conventionally known technique to decolorize, after obtaining the recorded images, a hue that is produced by the above-mentioned dye and that remains on the image-recording material, by additional irradiation with light that can be absorbed by the dye to thereby carry out photodecomposition of the dye. However, since the decolorization is insufficient in some cases, problems such as a reduction of distinctness of hue or contrast and requirement of a long time for decolorization may occur. Accordingly, a need exists for further improvement.

### SUMMARY OF THE INVENTION

It is a task of the present invention to overcome the problems in the prior art and to achieve the following.

Accordingly, an object of the present invention is to provide a novel cyanine-based dye which is highly decomposable by a radical and excellent in decolorization.

Another object of the present invention is to provide a photopolymerizable composition having high sensitivity not only to ultraviolet light but also to visible-to-infrared light.

A further object is to provide a recording material which enables image recording with high sensitivity by use not only of ultraviolet light but also of visible-to-infrared light and which exhibits excellent decolorization in non-image portions (background) and can form sharp, high-contrast black and white or color images in a perfectly dry system requiring no developing solution and producing no waste.

These objectives can be achieved by the following means.

According to a first aspect, the present invention is a photopolymerizable composition comprising a polymerizable compound having an ethylenically unsaturated bond, a compound represented by following general formula (1), and a radical generator capable of interacting with the compound represented by the general formula (1) and generating a radical:

[chemical structure]

Wherein, in the general formula (1):R¹ represents an aliphatic group having a triple bond, and R² represents a hydrogen atom, an aliphatic group, or an aromatic group; L¹, L², and L³ each independently represents a methine group that may have a substituent, and if L¹, L², and L³ each represents a methine group that has a substituent, the substituents may join together to form an unsaturated aliphatic ring or an unsaturated heterocycle; Z¹ and Z² each independently represents an atomic group that forms a 5-membered or 6-membered nitrogen-containing heterocycle, an aromatic ring may be condensed with the nitrogen-containing heterocycle and the nitrogen-containing heterocycle, and the aromatic ring condensed with the nitrogen-containing heterocycle may each have a substituent; n represents 0, 1, 2, or 3; and X⁻ represents a group capable of forming an anion.

According to a second aspect, the present invention is a cyanine-based organic dye represented by the following general formula (3):

[chemical structure]

in which general formula (3) R³³, R¹⁴, R¹⁵, R¹⁶, R¹⁷, and R¹⁸ each represents a hydrogen atom, an aliphatic group, or an aromatic group; R¹⁹ represents a bivalent aliphatic group; L²¹, L²², and L²³ each independently represents a methine group that may have a substituent, and, if L²¹, L²², and L²³ each represents a methine group that has a substituent, the substituents may join together to form an unsaturated aliphatic ring or an unsaturated heterocycle; Z²¹ and Z²² are benzene rings, with which other benzene rings may be condensed, and the benzene rings Z²¹ and Z²² and benzene rings condensed therewith may each have a substituent; n” represents 0, 1, 2, or 3; and X⁻ represents a group capable of forming an anion.

### DETAILED DESCRIPTION OF THE PREFERRED EMBODIMENTS

A cyanine-based organic dye of the present invention is a novel cyanine dye characterized by excellent decolorization by a radical.

A photopolymerizable composition of the present invention is characterized in that it contains a compound represented by the following general formula (1) as a compound, (i.e., a spectral sensitizer) capable of interacting with a radical generator. A recording material is characterized in that a recording layer on a support contains the above-mentioned photopolymerizable composition of the present invention together with color-forming components and the like.

The photopolymerizable composition of the present invention is explained below. Through this explanation, details of the cyanine-based organic dye and the recording material are given.

<Photopolymerizable Composition>

The photopolymerizable composition of the present invention contains a polymerizable compound having an ethylenically unsaturated bond, a compound represented by the following general formula (1), and a radical generator capable of generating a radical by interacting with this compound. As necessary, the photopolymerizable composition of the present invention may contain other components.

(Polymerizable Compound Having an Ethylenically Unsaturated Bond)

The photopolymerizable composition of the present invention contains the polymerizable compound having an ethylenically unsaturated bond (this compound is hereinafter referred to as “polymerizable compound” upon occasion).

The polymerizable compound is a compound having in the molecule thereof at least one ethylenically unsaturated bond. The polymerizable compound is not particularly limited and can be selected according to purposes. Examples of the polymerizable compound include acrylic derivatives such as acrylic esters and acrylic amides and the like acrylic acid and salts thereof, methacrylic derivatives such as methacrylic esters and methacrylic amides and the like methacrylic acid and salts thereof, maleic anhydride, maleic esters, itaconic acid, itaconic esters, styrenes, vinyl ethers, vinyl esters, N-vinyl heterocycles, allyl ethers, allyl esters and the like.

The polymerizable compound contains one, two, or more, olefinic double bonds and may be any of a low-molecular-weight (i.e., monomeric) compound and a high-molecular-weight (i.e., polymeric) compound.

Examples of monomers containing a double bond include alkyl or hydroxyalkyl acrylates and methacrylates, such as methyl acrylate, ethyl acrylate, butyl acrylate, 2-ethylhexyl acrylate, 2-hydroxyethyl acrylate, isobornyl acrylate, methyl methacrylate, ethyl methacrylate and the like. Also, silicone acrylates are advantageous.

Other examples include acrylonitrile, acrylamide, methacrylamide, N-substituted (meth)acrylamide, vinyl esters such as vinyl acetate, vinyl ethers such as isobutyl vinyl ether, styrene, alkyl- and halo-styrene, N-vinylpyrrolidone, vinyl chloride, vinylidene chloride and the like.

Examples of monomers containing two or more double bonds include diacrylates of ethylene glycol, propylene glycol, neopentyl glycol, hexamethylene glycol, bisphenol A and the like 4,4′-bis(2-acrylolyloxyethoxy)diphenylpropane, trimethylolpropane triacrylate, pentaerythritol triacrylate or tetraacrylate, vinyl acrylate, divinylbenzene, divinyl succinate, diallyl phthalate, triallyl phosphate, triallyl isocyanurate, tris(2-acryloylethyl)isocyanurate and the like.

Examples of multi-unsaturated compounds having a relatively high molecular weight (i.e., oligomeric compounds) include epoxy resins having a (meth)acryl group, polyesters having a (meth)acryl group, polyesters containing a vinyl ether or epoxy group, polyurethane, polyether and the like. Further, examples of unsaturated oligomers include unsaturated polyester resins which are usually produced from maleic acid, phthalic acid, and one or more diols, and have a molecular weight of about 500 to 3000. In addition, it is also possible to use vinyl ether monomers and oligomers, and oligomers which have polyester, polyurethane, polyether, polyvinyl ether, or epoxy main chains and are endstopped with maleate. Particularly suitable is a combination of an oligomer having a vinyl ether group and a polymer described in WO90/01512. Also suitable is a copolymer of a vinyl ether and a maleic acid-functionalized monomer. These oligomers may also belong to prepolymers.

Particularly suitable examples are an ester of an ethylenically unsaturated carboxylic acid and a polyol or a polyepoxide, a polymer having on a main or side chain thereof an ethylenically unsaturated group such as an unsaturated polyester, polyamide, or polyurethane, or a copolymer thereof, alkyd resin, a polybutadiene or butadiene copolymer, a polyisoprene or isoprene copolymer, a polymer or copolymer having on a side chain thereof a (meth)acryl group, or blend of one or more of these polymers.

Examples of unsaturated carboxylic acids include unsaturated fatty acids such as acrylic acid, methacrylic acid, crotonic acid, itaconic acid, cinnamic acid, linoleic acid, and oleic acid. Among these acids, acrylic acid and methacrylic acid are preferable.

Aromatic polyols, and aliphatic and alicyclic polyols in particular, are suitable as polyols. Examples of aromatic polyols include hydroquinone, 4,4′-dihydroxydiphenyl, 2,2′-di(4-hydroxydiphenyl)propane, novolak, and resorcinol. Examples of polyepoxides are those based on polyols, aromatic polyols in particular, or epichlorohydrin. Examples of other suitable polyols are polymers and copolymers having on a polymer chain or side chain thereof a hydroxyl group such as polyvinyl alcohol, and copolymers thereof, and polyhydroxyalkyl methacrylate and copolymers thereof. In addition, an oligoester having a hydroxyl terminal group is also suitable as a polyol.

Examples of aliphatic and alicyclic polyols are preferably alkylene diols having 2 to 12 carbon atoms such as ethylene glycol, 1,2- or 1,3-propanediol, 1,2-, 1,3-, or 1,4-butanediol, pentanediol, hexanediol, octanediol, dodecanediol, diethylene glycol, triethylene glycol, polyethylene glycol having a molecular weight of preferably 200 to 1500, 1,3-cyclopentanediol, 1,2-, 1,3-, or 1,4-cyclohexanediol, 1,4-dihydroxymethylcyclohexane, glycerol, tris(β-hydroxyethyl)amine, trimethylolethane, trimethylolpropane, pentaerythritol, dipentaerythritol, and sorbitol.

The polyol can be partially or completely esterified by one unsaturated carboxylic acid or by different unsaturated carboxylic acids. In a partially esterified product, a free hydroxyl group can be modified. For example, the free hydroxyl group can be etherified or esterified by another carboxylic acid.

Examples of esters include the following compounds. That is, trimethylolpropane triacrylate, trimethylolethane triacrylate, trimethylolpropane trimethacrylate, trimethylolethane trimethacrylate, tetramethylene glycol dimethacrylate, triethylene glycol dimethacrylate, tetraethylene glycol diacrylate, pentaerythritol diacrylate, pentaerythritol triacrylate, pentaerythritol tetraacrylate, dipentaerythritol diacrylate, dipentaerythritol triacrylate, dipentaerythritol tetraacrylate, dipentaerythritol pentaacrylate, dipentaerythritol hexaacrylate, tripentaerythritol octaacrylate, pentaerythritol dimethacrylate, pentaerythritol trimethacrylate, dipentaerythritol dimethacrylate, dipentaerythritol tetramethacrylate, tripentaerythritol octamethacrylate, pentaerythritol diitaconate, dipentaerythritol trisitaconate, dipentaerythritol pentaitaconate, dipentaerythritol hexaitaconate, ethylene glycol diacrylate, 1,3-butanediol diacrylate, 1,3-butanediol dimethacrylate, 1,4-butanediol diitaconate, sorbitol triacrylate, sorbitol tetraacrylate, pentaerythritol-modified triacrylate, sorbitol tetramethacrylate, sorbitol pentaacrylate, sorbitol hexaacrylate, oligoester acrylate or methacrylate, glycerol diacrylate or triacrylate, 1,4-cyclohexane diacrylate, bisacrylate or bismethacrylate of polyethylene glycol having a molecular weight of 200 to 1500, and mixtures of the foregoing compounds.

Further, suitable as the polymerizable compound are amides made up of unsaturated carboxylic acids that are the same or different and aromatic, alicyclic, or aliphatic polyamines having preferably 2 to 6, particularly preferably 2 to 4, amino groups.

Examples of such polyamines are ethylenediamine, 1,2- or 1,3-propylenediamine, 1,2-, 1,3-, or 1,4-butylenediamine, 1,5-pentylenediamine, 1,6-hexylenediamine, octylenediamine, dodecylenediamine, 1,4-diaminocyclohexane, isophoronediamine, phenylenediamine, bisphenylenediamine, di-β-aminoethyl ether, diethylene triamine, triethylene tetramine, and di(β-aminoethoxy)- or di(β-aminopropoxy) ethane. Other suitable polyamines are polymers and copolymers having an additional amino group preferably on a side chain and oligo-amides having a terminal amino group. Examples of such unsaturated amides are methylenebisacrylamide, 1,6-hexamethylenebisacrylamide, diethylenetriaminetrismethacrylamide, bis(methacrylamidepropoxy)ethane, β-methacrylamidoethyl methacrylate, N-[(β-hydroxyethoxy)ethyl]acrylamide, and so on.

Suitable unsaturated polyesters and polyamides can be derived, for example, from maleic acid and diols or diamines. Some of the maleic acid may be replaced with another dicarboxylic acid. These can be used together with an ethylenically unsaturated comonomer, for example, styrene. The polyesters and polyamides can also be derived from dicarboxylic acid and ethylenically unsaturated diols or diamines, particularly from those having a relatively long chain, for example, 6 to 20 carbon atoms. An example of a polyurethane is one made up of a saturated or unsaturated diisocyanate and an unsaturated or saturated diol.

Polybutadiene and polyisoprene, as well as copolymers thereof, are conventionally known. Examples of suitable comonomers are olefins, such as ethylene, propene, butene, and hexene, (meth)acrylate, acrylonitrile, styrene, and vinyl chloride. Similarly, polymers having on a side chain thereof a (meth)acrylate group are also known. For example, such a polymer can be obtained as a reaction product from a novolak-based epoxy resin and (meth)acrylic acid. Alternatively, such a polymer may be a homopolymer or a copolymer of a hydroxyalkyl derivative produced by esterification with vinyl alcohol or (meth)acrylic acid; or a homopolymer or a copolymer of a (meth)acrylate produced by esterification with an hydroxyalkyl (meth)acrylate.

Depending on application of the photopolymerizable composition, the polymerizable compound may be a compound having in the structure thereof a site that exhibits another function, for example, a site for accelerating or inhibiting a color-forming reaction of color-forming components that constitute image portions when the photopolymerizable composition is utilized in a recording material. These are described later.

The content of the polymerizable compound having the ethylenically unsaturated bond is normally 10 to 99% by weight, preferably 30 to 95% by weight, of the total weight of the photopolymerizable composition.

(Compounds Represented by the General Formula (1))

In the present invention, the photopolymerizable composition contains a compound represented by the general formula (1) as a spectral sensitizing dye. This dye is a cyanine-based dye and functions to spectrally sensitize the radical generator. Accordingly, when the photopolymerizable composition containing the radical generator is irradiated with visible-to-infrared light corresponding to absorption of the dye, radical generation by the radical generator can be accelerated even if the radical generator has no absorption in that wavelength region. In addition, because the dye is highly decolorized by the irradiation, use of the dye is advantageous in inhibition of fogging in the background and in formation of sharp images having high contrast on a recording material that utilizes the photopolymerizable composition, as described later.

[chemical structure]

In the general formula (1), R¹ represents an aliphatic group having a triple bond. Preferably, the aliphatic group is a group represented by —R¹⁹—C≡C—R¹⁸ where R¹⁸ represents a hydrogen atom, an aliphatic group, or an aromatic group, and R¹⁹ represents a bivalent aliphatic group.

If R¹⁸ represents an aliphatic group, examples of the aliphatic group include an alkyl group, a substituted alkyl group, an alkenyl group, a substituted alkenyl group, an alkynyl group, a substituted alkynyl group, an aralkyl group, a substituted aralkyl group and the like. Among these groups, the alkyl group, the substituted alkyl group, the alkenyl group, the substituted alkenyl group, the aralkyl group, and the substituted aralkyl group are preferable; and the alkyl group and the substituted alkyl group are particularly preferable.

The aliphatic group may be an alicyclic group or a chain-like aliphatic group. The chain-like aliphatic group may be branched.

Examples of the alkyl group include a straight-chain alkyl group, a branched alkyl group, and a cyclic alkyl group. The number of carbon atoms in the alkyl group is preferably 1 to 30 and more preferably 1 to 20. The range of the preferable number of carbon atoms in the alkyl portion of the substituted alkyl group is the same as in the alkyl group. The alkyl group may be an alkyl group having a substituent or an alkyl group having no substituent.

Examples of the alkyl group include methyl, ethyl, propyl, butyl, pentyl, hexyl, octyl, 2-ethylhexyl, decyl, dodecyl, octadecyl, cyclohexyl, cyclopentyl, neopentyl, isopropyl, and isobutyl groups and the like.

Examples of the substituent of the substituted alkyl group include the following groups. A carboxyl group, a sulfo group, a cyano group, a halogen atom (e.g., a fluorine, chlorine, or bromine atom), a hydroxy group, an alkoxycarbonyl group having 30 or less carbon atoms (e.g., a methoxycarbonyl, ethoxycarbonyl, or benzyloxycarbonyl group), an alkylsulfonylaminocarbonyl group having 30 or less carbon atoms, an arylsulfonylaminocarbonyl group, an alkylsulfonyl group, an arylsulfonyl group, an acylaminosulfonyl group having 30 or less carbon atoms, an alkoxy group having 30 or less carbon atoms (e.g., a methoxy, ethoxy, benzyloxy, phenoxyethoxy, or phenethyloxy group or the like), an alkylthio group having 30 or less carbon atoms (e.g., a methylthio, ethylthio, or methylthioethylthioethyl group or the like), an aryloxy group having 30 or less carbon atoms (e.g., a phenoxy, p-tolyloxy, 1-naphthoxy, or 2-naphthoxy group or the like), a nitro group, an alkyl group having 30 or less carbon atoms, an alkoxycarbonyloxy group, an aryloxycarbonyloxy group, an acyloxy group having 30 or less carbon atoms (e.g., an acetyloxy or propionyloxy group or the like), an acyl group having 30 or less carbon atoms (e.g., an acetyl, propionyl, or benzoyl group or the like), a carbamoyl group (e.g., a carbamoyl, N,N-dimethylcarbamoyl, morpholinocarbamoyl, or piperidinocarbamoyl group or the like), a sulfamoyl group (e.g., a sulfamoyl, N,N-dimethylsulfamoyl, morpholinosulfamoyl, or piperidinosulfamoyl group or the like), an aryl group having 30 or less carbon atoms (e.g., a phenyl, 4-chlorophenyl, 4-methylphenyl, or α-naphthyl group or the like), a substituted amino group (e.g., an amino, alkylamino, dialkylamino, arylamino, diarylamino, or acylamino group or the like), a substituted ureido group, a substituted phosphono group, a heterocyclic group, and so on. In the examples listed above, the carboxyl group, sulfo group, hydroxyl group, and phosphono group may be in a salt state. In this case, examples of a cation constituting the salt include G⁺ and the like, which are described later.

Examples of the alkenyl group include a straight-chain alkenyl group, a branched alkenyl group, and a cyclic alkenyl group. The number of carbon atoms in the alkenyl group is preferably 2 to 30 and more preferably 2 to 20. The alkenyl group may be an alkenyl group having a substituent or an alkenyl group having no substituent. The range of the preferable number of carbon atoms in the alkenyl portion of the substituted alkenyl group is the same as in the alkenyl group.

Examples of the substituents of the substituted alkenyl groups include the same substituents as in the case of the substituted alkyl groups.

Examples of the alkynyl group include a straight-chain alkynyl group, a branched alkynyl group, and a cyclic alkynyl group. The number of carbon atoms in the alkynyl group is preferably 2 to 30 and more preferably 2 to 20. The alkynyl group may be an alkynyl group having a substituent or an alkynyl group having no substituent. The range of the preferable number of carbon atoms in the alkynyl portion of the substituted alkynyl group is the same as in the alkynyl group.

Examples of the substituents of the substituted alkynyl groups include the same substituents as in the case of the substituted alkyl groups.

Examples of the aralkyl group include a straight-chain aralkyl group, a branched aralkyl group, and a cyclic aralkyl group. The number of carbon atoms in the aralkyl group is preferably 7 to 35 and more preferably 7 to 25. The aralkyl group may be an aralkyl group having a substituent or an aralkyl group having no substituent. The range of the preferable number of carbon atoms in the aralkyl portion of the substituted aralkyl group is the same as in the aralkyl group.

Examples of the substituents of the substituted aralkyl groups include the same substituents as in the case of the substituted alkyl groups.

If R¹⁸ represents an aromatic group, examples of the aromatic group include an aryl group and a substituted aryl group. The number of carbon atoms in the aryl group is preferably 6 to 30 and more preferably 6 to 20. The range of the preferable number of carbon atoms in the aryl portion of the substituted aryl group is the same as in the aryl group. Examples of the aryl group include a phenyl group, an α-naphthyl group, and a -naphthyl group.

Examples of the substituents of the substituted aryl groups include the same substituents as in the case of the substituted alkyl groups.

R¹⁹ represents a bivalent aliphatic group. Examples of the bivalent aliphatic group include bivalent aliphatic groups that are derived by eliminating one hydrogen atom from the terminal carbon atom of a monovalent aliphatic group represented by R¹⁸. Specific examples of the bivalent aliphatic groups include an alkylene group, a substituted alkylene group, an alkenylene group, a substituted alkenylene group and the like. Among these groups, the alkylene group and the substituted alkylene group are preferable.

The aliphatic group may be an alicyclic group or a chain-like aliphatic group. The chain-like aliphatic group may be branched.

The above-mentioned alkylene group, substituted alkylene group, alkenylene group, and substituted alkenylene group may be straight-chain, branched, or cyclic. Examples of these groups include those derived from the scope of aliphatic groups represented by R¹⁸. Preferred examples of these groups are those derived from the scope of preferred aliphatic groups represented by R¹⁸.

Among these groups, aliphatic groups represented by R¹ are preferably the following groups and particularly preferably groups in which R¹⁹ is CH₂, from the standpoint of raising sensitivity and improving a decolorization property.

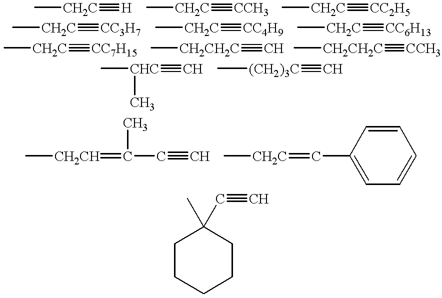

In the general formula (1), R² represents a hydrogen atom, an aliphatic group, or an aromatic group. The aliphatic group and aromatic group have the same meaning as the aliphatic group and aromatic group, respectively, represented by R¹⁸. Particularly preferable is case where R² represents the same group as R¹.

In the general formula (1), L¹, L², and L each independently represents a methine group that may have a substituent. If L¹, L², and L³ each represents a methine group that has a substituent, the substituents may join together to form an unsaturated aliphatic ring or an unsaturated heterocycle.

Examples of the substituent of the methine group include substituted amino groups (e.g., amino, alkylamino, dialkylamino, arylamino, diarylamino, and acylamino groups and the like), substituted oxy groups (e.g., hydroxyl, alkoxy, acyloxy, aryloxy, alkoxycarbonyloxy, and aryloxycarbonyloxy groups and the like), substituted mercapto groups (e.g., alkylmercapto and arylmercapto groups and the like), halogen atoms, aliphatic groups, and aromatic groups.

Examples of halogen atoms include a fluorine atom, a bromine atom, and a chlorine atom. The aliphatic group and aromatic group have the same meaning as the aliphatic group and aromatic group, respectively, represented by R¹⁸. The substituents of the substituted amino groups, the substituted oxy groups, and the substituted mercapto groups have the same meaning as the substituents of the substituted alkyl group represented by R¹⁸.

As a methine group represented by L¹, L², or L³, an unsubstituted methine group, or if the methine group is a substituted methine group, a methine group bearing a halogen atom or an aliphatic group, or a methine group whose substituents join together to form a cyclopentene ring or a cyclohexene ring, is particularly preferable.

In the general formula (1), Z¹ and Z² each independently represents an atomic group that forms a 5-membered or 6-membered nitrogen-containing heterocycle wherein an aromatic ring may be condensed with the nitrogen-containing heterocycle, and the nitrogen-containing heterocycle and the aromatic ring condensed with the nitrogen-containing heterocycle may have substituents. Examples of the nitrogen-containing heterocycle include an oxazole ring, a thiazole ring, a selenazole ring, a pyrrole ring, a pyrroline ring, an imidazole ring, and a pyridine ring. 5-membered rings are more preferable than 6-membered rings. An aromatic ring (such as a benzene ring, naphthalene ring, or the like) may be condensed with the nitrogen-containing heterocycle, and the nitrogen-containing heterocycle and the ring condensed with the nitrogen-containing heterocycle may have a substituent. Examples of the substituent include the same substituents as those of the substituted alkyl group represented by R¹⁸.

In the general formula (1), n represents 0, 1, 2, or 3.

In the general formula (1), X⁻ represents a group capable of forming an anion. Examples of the anion include a halogen ion (Cl⁻, Br⁻, or I⁻), a p-toluenesulfonate ion, an ethylsulfate ion, a 1,5-disulfonaphthalene dianion, PF₆⁻, BF₄⁻, ClO₄⁻ and the like. X may be a substituent borne by a substitutable position in the cation portion of the general formula (1). In this case, the compound represented by the general formula (1) forms an inner salt.

Among the cyanine-based dyes represented by the general formula (1), the cyanine-based dyes represented by the following general formula (2) are preferable because of superior sensitivity and decolorization property.

[chemical structure]

In the general formula (2), R¹¹ represents an aliphatic group having a triple bond, and R¹² represents a hydrogen atom, an aliphatic group, or an aromatic group. R¹¹ and R¹² have the same meaning as R¹ and R², respectively, in the general formula (1). The same applies to preferred examples. L¹¹, L¹², and L¹³ each independently represents a methine group that may have a substituent. If L¹¹, L¹², and L¹³ each represents a methine group that has a substituent, the substituents may join together to form an unsaturated aliphatic ring or an unsaturated heterocycle. The methine groups represented by L¹¹, L¹², and L¹³ have the same meaning as the methine groups represented by L¹, L², and L³ in the general formula (1). The same applies to preferred examples.

In the general formula (2), Y¹¹ and Y¹² each independently represents —CR²⁸R²⁹—, —NR³⁰—, —O—, —S—, or Se—. R²⁸, R²⁹, and R³⁰ each independently represents a hydrogen atom, an aliphatic group, or an aromatic group; and R²⁸ and R²⁹ may each be an atomic group which joins together to form a ring. The aliphatic group and the aromatic group have the same meaning as the aliphatic group and the aromatic group, respectively, represented by R¹⁸. An alkyl group or a substituted alkyl group is particularly preferable as the aliphatic group.

As Y¹¹ or Y¹², —CR²⁸R²⁹— is particularly preferable. R²⁸ and R²⁹ are each preferably an alkyl group.

In the general formula (2), other benzene rings may be condensed with benzene rings Z¹¹ and Z¹² , and the benzene rings Z¹¹ and Z¹² and the condensed rings may have a substituent. Examples of the substituent include the same substituents as those of the substituted alkyl group represented by R¹⁸.

n′ represents 0, 1, 2, or 3. X⁻ represents a group capable of forming an anion and has the same meaning as X⁻ in the general formula (1). The same applies to the preferred examples.

Among the compounds represented by the general formula (2), the cyanine-based dyes represented by the following general formula (3) are particularly preferable. These cyanine-based dyes are highly decomposable by a radical from outsise, and have excellent decolorization property in particular.

[chemical structure]

In the general formula (3), R¹³ , R¹⁴ , R¹⁵ , R¹⁶ , R¹⁷ , and R¹⁸ each represents a hydrogen atom, an aliphatic group, or an aromatic group. The aliphatic group and aromatic group have the same meaning as the aliphatic group and aromatic group, respectively, represented by R¹⁸ in the general formula (1). The same applies to preferred examples. R¹⁹ represents a bivalent aliphatic group and has the same meaning as R¹⁹ in the general formula (1). The same applies to preferred examples.

In the general formula (3), L²¹, L²², and L²³ each independently represents a methine group that may have a substituent. If L²¹, L²², and L²³ each represents a methine group that has a substituent, the substituents may join together to form an unsaturated aliphatic ring or an unsaturated heterocycle. The methine groups represented by L²¹, L²², and L²³ have the same meaning as the methine groups represented by L¹, L², and L³ in the general formula (1). The same applies to preferred examples.

Other benzene rings may be condensed with benzene rings Z²¹ and Z²² and the benzene rings Z²¹ and Z²² and the condensed rings may have a substituent. Z²¹ and Z²² have the same meaning as Z¹ and Z² in the general formula (1). Examples of the substituent include the same substituents as those of Z¹ and Z².

n″ represents 0, 1, 2, or 3. X⁻ represents a group capable of forming an anion and has the same meaning as X⁻ in the general formula (1). The same applies to preferred examples.

Specific examples of the compounds represented by the general formulae (1) to (3) (exemplary compounds) are given below. However, it should be noted that the present invention is not limited to these examples.

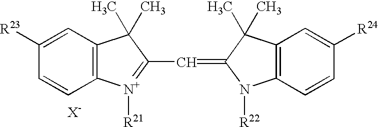

| No. | R²¹ | R²² | R²³ | R²⁴ | X |
|---|---|---|---|---|---|
| 1 | —CH₂C≡CH | —CH₃ | —H | —H | ClO₄ |
| 2 | —CH₂C≡CH | —CH₃ | —SO₂CH₃ | —H | BF₄ |

[chemical structure]

| No. | R²¹ | R²² | R²³ | R²⁴ | R²⁵ | X |
|---|---|---|---|---|---|---|
| 3 | —CH₂C≡CH | —CH₂C≡CH | —H | —H | —H | CF₃SO₃ |
| 4 | —CH₂C≡CH | —CH₂C≡CH | —H | —H | 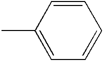 | CF₃SO₃ |
| 5 | —CH₂C≡CH | —CH₂C≡CH | —H | —H | —CH₃ | CF₃SO₃ |
| 6 | —CH₂C≡CH | —CH₂C≡CH | —Cl | —Cl | —H | 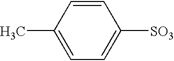 |
| 7 | —CH₂C≡CH | —CH₂C≡CH | —CO₂C₂H₅ | —CO₂C₂H₅ | —H | CF₃SO₃ |
| 8 | —CH₂C≡CH | —CH₂C≡CH | —SO₂CH₃ | —SO₂CH₃ | —H | CF₃SO₃ |
| 9 | —CH₂CH₂C≡CH | —CH₂CH₂C≡CH | —SO₂CH₃ | —SO₂CH₃ | —H | CF₃SO₃ |
| 10 | —CH₂C≡CCH₃ | —CH₂C≡CCH₃ | —SO₂CH₃ | —SO₂CH₃ | —H | CF₃SO₃ |
| 11 | —CH₂C≡CC₂H₅ | —CH₂C≡CC₂H₅ | —SO₂CH₃ | —CSO₂CH₃ | —H | CF₃SO₃ |
| 12 | —CH₂C≡CCH₃ | —CH₂C≡CCH₃ | —SO₂CH₃ | —SO₂CH₃ | —CH₃ | CF₃SO₃ |
| 13 | —CH₂C≡CC₄H₉ | —CH₂C≡CC₄H₉ | —SO₂CH₃ | —SO₂CH₃ | —C₂H₅ | CF₃SO₃ |
| 14 | —CH₂C≡CC₇H₁₅ | —CH₂C≡CC₇H₁₅ | —SO₂CH₃ | —SO₂CH₃ | 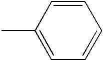 | CF₃SO₃ |
| 15 | —CH₂C≡CCH₃ | —CH₂C≡CCH₃ | —SO₂CH₃ | —SO₂CH₃ | 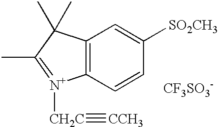 | CF₃SO₃ |

| | |
|---|---|
| | 16 |
| [chemical structure] | |
| | 17 |
| [chemical structure] | |
| | 18 |
| 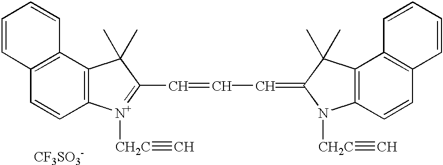 | |
| | 19 |
| [chemical structure] | |
| | 20 |
| [chemical structure] | |
| | 21 |
| [chemical structure] | |
| | 22 |
| [chemical structure] | |

[chemical structure]

| No. | Y¹¹ | Y¹² | R²¹ | R²² | R²³ | R²⁴ | R²⁵ | X |
|---|---|---|---|---|---|---|---|---|
| 23 | S | S | —CH₂C≡CH | —CH₂C≡CH | —H | —H | —H | Br |
| 24 | S | S | —CH₂C≡CCH₃ | —CH₂C≡CCH₃ | —H | —H | —H | CF₃SO₃ |
| 25 | S | S | —CH₂C≡CCH₃ | —CH₂C≡CCH₃ | —SO₂CH₃ | —SO₂CH₃ | —H | CF₃SO₃ |
| 26 | O | O | —CH₂C≡CH | —CH₂C≡CH | —H | —H | —H | CF₃SO₃ |
| 27 | O | O | —CH₂C≡CCH₃ | —CH₂C≡CCH₃ | —SO₂CH₃ | —SO₂CH₃ | —CH₃ | CF₃SO₃ |
| 28 | 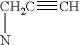 | 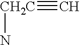 | —CH₂C≡CH | —CH₂C≡CH | —H | —H | —H | CF₃SO₃ |
| 29 | 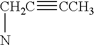 | 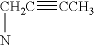 | —CH₂C≡CCH₃ | —CH₂C≡CCH₃ | —H | —H | —H | CF₃SO₃ |

| | |
|---|---|
| | 30 |
| 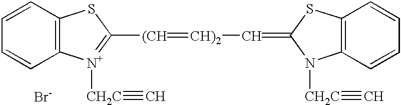 | |
| | 31 |
| 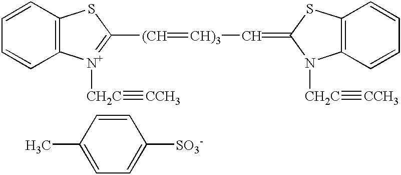 | |
| | 32 |
| 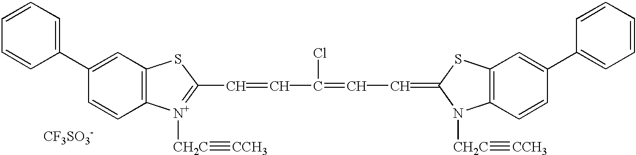 | |
| | 33 |
| [chemical structure] | |
| | 34 |
| 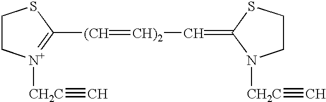 | |
| | 35 |
| [chemical structure] | |

Synthesis examples of the compounds represented by the general formula (3) are given below. The number in parentheses for each exemplary compound indicates the number (No.) attached to the exemplary compounds listed above.

### SYNTHESIS EXAMPLE 1

Synthesis of Exemplary Compound (No.3)

2 g of a quaternary salt of indolenine shown below, 0.68 g of triethyl orthoformate, and 5 mL of pyridine were weighed into a three-neck flask. These contents were stirred for 1 hour under a refluxing condition. After that, this reaction solution was poured into water and a mixture was extracted with ethyl acetate. This extract was dried using magnesium sulfate, filtered, and concentrated (i.e., solvent was distilled off) so as to obtain a crude dye. The crude dye thus obtained was purified by silica gel column chromatography (eluent: ethyl acetate). As a result, the objfect exemplary compound (No.3) was obtained with a 50% yield.

¹H-NMR (CDCl₃): δ 1.76(s, 12H), 2.40(s, 2H), 5.00(s, 4H) 6.80(d, 2H), 7.24-7.50(m, 4H), 8.50(t, 1H)

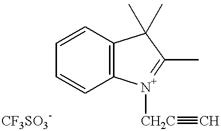

### SYNTHESIS EXAMPLES 2 TO 4

In the same way as in Synthesis Example 1, exemplary compounds (No. 8, No. 9, and No. 10) were synthesized. The respective results of ¹H-NMR (CDCl₃) analysis are given below.

Exemplary Compound (No.8)

¹H-NMR ((CD₃)₂CO): δ 1.98(s, 12H), 2.80(s, 2H), 3.20(s, 6H) 5.28(s, 4H), 6.92(d, 2H), 7.81(d, 2H), 8.12(d, 2H), 8.21(s, 2H), 8.86 (t, 1H)

Exemplary Compound (No.9)

¹H-NMR (CDCl₃): δ 1.81 (s, 12H), 1.84 (s, 2H), 2.95 (t, 4H), 3.14 (s, 6H), 4.49 (t, 4H), 7.12 (d, 2H), 7.52 (d, 2H), 7.94 (s, 2H), 8.01 (d, 2H), 8.52 (t, 1H)

Exemplary Compound (No.10)

¹H-NMR (CDCl₃): δ 1.80 (s, 12H), 1.85 (s, 6H), 3.14 (s, 6H) 4.99 (s, 4H), 6.81 (d, 2H), 7.44 (d, 2H), 7.95 (s, 2H), 8.04 (d, 2H), 8.57 (t, 1H)

The compounds represented by the general formulae (1) to (3) may be used singly or in combinations of two or more.

The content of the compound represented by any of the general formulae (1) to (3) in the photopolymerizable composition is preferably 0.01 to 5 parts by weight, more preferably 0.05 to 2 parts by weight, for 1 part by weight of the radical generators described later.

If the content is less than 0.01 parts by weight, the photopolymerization sensitivity may decrease, whereas if the content exceeds 5 parts by weight, a long time may be required for the decolorization of the dye.

The incorporation of the compounds represented by the general formulae (1) to (3) into the photopolymerizable composition makes it possible to raise the photopolymerization sensitivity of the photopolymerizable composition so that the sensitivity not only to ultraviolet light but also to visible-to-infrared light is raised. In addition, the compounds represented by the general formulae (1) to (3) are highly decomposable by the radical to be generated from the radical generator with which the compounds interact. As a result, these compounds are excellent in decolorization and can be sufficiently decolorized without requiring a long time. Therefore, as described later, it is possible to decrease coloration in non-image portions (the background) and to form sharp, high-contrast images even in a perfectly dry system without using a developing solution or the like.

(Radical Generator)

The photopolymerizable composition of the present invention contains a radical generator capable of interacting with the spectral sensitizer to generate a radical. The presence of the radical generator together with the spectral sensitizer enables the radical generator to be sensitized by irradiation with light having wavelengths falling within the spectral absorption wavelength region in a highly sensitive manner, and to generate a radical in a highly efficient manner. Accordingly, the sensitivity is raised and the generation of the radical can be controlled by use of any light source emitting light having wavelengths falling within a visible-to-infrared light region.

One or two, or more, kinds of the radical generator, which are selected from radical generators capable of initiating the polymerization of the polymerizable compound contained in the photopolymerizable composition, can be used as the radical generator described above.

Examples of the radical generator include aromatic ketones such as benzophenone, camphorquinone, 4,4-bis(dimethylamino)benzophenone, 4-methoxy-4′-dimethylaminobenzophenone, 4,4′-dimethoxybenzophenone, 4-dimethylaminobenzophenone, 4-dimethylaminoacetophenone, benzylanthraquinone, 2-tert-butylanthraquinone, 2-methylanthraquinone, xanthone, thioxanthone, 2-chlorothioxanthone, 2,4-diethylthioxanthone, fluorenone, acridone, (bis)acylphosphine oxides such as bis(2,4,6-trimethylbenzoyl)-phenylphosphine oxide and the like, acylphosphine oxides such as. Lucirin TPO and the like, α-hydroxy or α-aminoacetophenones, α-hydroxycydoalkylphenyl ketunes and dialkoxyacetophenones; benzoin and benzoin ethers such as benzoin methyl ether, benzoin ethyl ether, benzoin isopropyl ether, benzoin phenyl ether and the like; dimers of 2,4,6-triarylimidazole such as a dimer of 2-(o-chlorophenyl)-4,5-diphenylimidazole, a dimer of 2-(o-chlorophenyl)-4,5-di(m-methoxyphenyl)imidazole, a dimer of 2-(o-fluorophenyl)-4,5-diphenylimidazole, a dimer of 2-(o-methoxyphenyl)-4,5-diphenylimidazole, a dimer of 2-(p-methoxyphenyl)-4,5-diphenylimidazole and the like, and compounds described in U.S. Pat. Nos. 3,784,557, 4,252,887, 4,311,783, 4,459,349, 4,410,621, 4,622,286, and others; polyhalogen compounds such as carbon tetrabromide, phenyltribromomethylsulfone, phenyltrichloromethyl ketone and the like; compounds described in JP-A No. 59-133428, Japanese Patent Application Publication JP-B No. 57-1819, JP-B No. 57-6096, and U.S. Pat. No. 3,615,455; s-triazine derivatives having a trihalogenated methyl group described in JP-A No. 58-29803 such as 2,4,6-tris(trichloromethyl)-triazine, 2-methoxy-4,6-bis(trichloromethyl)-s-triazine, 2-amino-4,6-bis(trichloromethyl)-s-triazine, 2-(p-methoxystyryl)-4,6-bis(trichloromethyl)-s-triazine and the like; organic peroxides described in JP-A No. 59-189340 such as methyl ethyl ketone peroxide, cyclohexanone peroxide, 3,3,5-trimethylcyclohexanone peroxide, benzoyl peroxide, di-t-butyl diperoxyisophthalate, 2,5-dimethyl-2,5-di(benzoylperoxy)hexane, t-butyl peroxybenzoate, a,a′-bis(t-butylperoxyisopropyl)benzene, dicumylperoxide, 3,3′,4,4′-tetra-(t-butylperoxycarbonyl)benzophenone and the like; azinium salts described in U.S. Pat. No. 4,743,530; organoboron compounds; phenylglyoxylates such as methyl phenylglyoxylate and the like; titanocenes such as bis(η⁵-2,4-cyclopentadiene-1-yl)-bis(2,6-difluoro-3-(1H-pyrrole-1-yl)-phenyl)titanium and the like; arene iron complexes such as η⁵-cyclopentadienyl-η⁶-cumenyl-iron (1⁺)-hexafluorophosphate(1⁻) and the like; diaryliodonium salts such as diphenyliodonium salts and the like; and triarylsulfonium salts such as triphenysulfonium salts and the like; and the like.

Examples of the radical generator in more detail and examples of other kinds of radical generators include those described in JP-A No. 10-45816, paragraphs [0067] to [0132].

In addition, a combination of two or more radical generators can also be used. Examples of the combination include a combination of a dimer of 2,4,5-triarylimidazole and mercaptobenzoxazole or the like, a combination of 4,4′-bis(dimethylamino)benzophenone, benzophenone, and benzoin methyl ether described in U.S. Pat. No. 3,427,161, a combination of benzoyl-N-methylnaphtothiazoline and 2,4-bis(trichloromethyl)-6-(4′-methoxyphenyl)-triazole described in U.S. Pat. No. 4,239,850, a combination of a dialkylaminobenzoate ester and dimethylthioxanthone described in JP-A No. 57-23602, a combination made up of 3 kinds of compounds such as 4,4′-bis(dimethylamino)benzophenone, benzophenone and a polyhalogenated-methyl compound described in JP-A No. 59-78339, and the like.

If the radical generator is made up of two or more kinds of compounds, it is preferable to use the combination of 4,4′-bis(diethylamino)benzophenone and benzophenone, the combination of 2,4-diethylthioxanthone and ethyl 4-dimethylaminobenzoate, or the combination of 4,4′-bis(diethylamino)benzophenone and the dimer of 2,4,5-triarylimidazole.

Among the above-listed radical generators, from the standpoint of capability to generate a radical effective for interacing with the dye in a and of raising the sensitivity, organoboron compounds, diaryliodonium salts, arene iron complexes, s-triazine derivatives having a trihalogenated methyl group, organic peroxides, titanocenes, dimer of 2,4,5-triarylimidazole, and azinium salt compound are preferable, and particularly preferable is an organoboron compound. The organoboron compound is preferable because, when a spectral sensitizing dye is used as the spectral sensitizing compound, the organoboron compound can satisfactorily decolorize spectral sensitizing dye that is present when the image is fixed by irradiation with light. The organoboron compound may be used in a combination with the above-described radical generators.

Examples of organoboron compounds include compounds represented by general formula (A) described later as well as organoboron compounds which are based on a spectral sensitizing dye and whose structure includes, as a cationic portion thereof, a cationic dye described in, for example, “Chemistry of Functional Dyes” (“Kinoosei Shikiso no Kagaku”, CMC Publishing Co., Ltd., 1981, pp.393-416) and “Coloring Materials” (“Shikizai”, 60 [4], 212-224(1987)). Examples of the above-mentioned organoboron compounds that are based on a spectral sensitizing dye include compounds described in, for example, JP-A Nos. 62-143044 and 1-138204, Japanese Patent Application National Publication No. 6-505287, and JP-A No. 4-261406 and the like.

Cationic dyes having a maximum absorption wavelength in a wavelength region of 300 nm or greater, preferably in a wavelength region of 400 to 1100 nm, can be used as the dye constituting the cationic portion of the above-mentioned organoboron compound that is based on a spectral sensitizing dye. Among these dyes, preferable are cationic methine dyes, polymethine dyes, triarylmethane dyes, indoline dyes, azine dyes, xanthene dyes, cyanine dyes, hemicyanine dyes, rhodamine dyes, azomethine dyes, oxazine dyes, acridine dyes, and the like. More preferable are cationic cyanine dyes, hemicyanine dyes, rhodamine dyes, and azomethine dyes.

Among the organoboron compounds, compounds represented by the following general formula (A) are preferable.

[chemical structure]

In the general formula (A), Rₐ¹, Rₐ², Rₐ³, and Rₐ⁴ each independently represents an aliphatic group, an aromatic group, a heterocyclic group, or —Si(Rₐ⁵) (Rₐ⁶)—Rₐ⁷.

If Rₐ¹ to Rₐ⁴ each represents an aliphatic group, examples of the aliphatic group include an alkyl group, a substituted alkyl group, an alkenyl group, a substituted alkenyl group, an alkynyl group, a substituted alkynyl group, an aralkyl group, a substituted aralkyl group and the like. Among these groups, the alkyl group, the substituted alkyl group, the alkenyl group, the substituted alkenyl group, the aralkyl group, and the substituted aralkyl group are preferable; and the alkyl group and the substituted alkyl group are particularly preferable.

The aliphatic group may be an alicyclic group or a chain-like aliphatic group. The chain-like aliphatic group may be branched.

Examples of the alkyl group include a straight-chain alkyl group, a branched alkyl group, and a cyclic alkyl group. The number of carbon atoms in the alkyl group is preferably 1 to 30 and more preferably 1 to 20. The alkyl group may be an alkyl group having a substituent or an alkyl group having no substituent. The range of the preferable number of carbon atoms in the alkyl portion of the substituted alkyl group is the same as in the alkyl group.

Examples of the alkyl group include methyl, ethyl, propyl, butyl, pentyl, hexyl, cyclopentyl, neopentyl, isopropyl, isobutyl, cyclohexyl, octyl, 2-ethylhexyl, decyl, dodecyl, octadecyl groups and the like.

Specific examples of the substituent of the substituted alkyl group include the following groups. A carboxyl group, a sulfo group, a cyano group, a halogen atom (e.g., a fluorine, chlorine, or bromine atom), a hydroxy group, an alkoxycarbonyl group having 30 or less carbon atoms (e.g., a methoxycarbonyl, ethoxycarbonyl, or benzyloxycarbonyl group), an alkylsulfonylaminocarbonyl group having 30 or less carbon atoms, an arylsulfonylaminocarbonyl group, an alkylsulfonyl group, an arylsulfonyl group, an acylaminosulfonyl group having 30 or less carbon atoms, an alkoxy group having 30 or less carbon atoms (e.g., a methoxy, ethoxy, benzyloxy, or phenethyloxy group or the like), an alkylthio group having 30 or less carbon atoms (e.g., a methylthio, ethylthio, or methylthioethylthioethyl group or the like), an aryloxy group having 30 or less carbon atoms (e.g., a phenoxy, p-tolyloxy, l-naphthoxy, or 2-naphthoxy group or the like), a nitro group, an alkyl group having 30 or less carbon atoms, an alkoxycarbonyloxy group, an aryloxycarbonyloxy group, an acyloxy group having 30 or less carbon atoms (e.g., an acetyloxy or propionyloxy group or the like), an acyl group having 30 or less carbon atoms (e.g., an acetyl, propionyl, or benzoyl group or the like), a carbamoyl group (e.g., a carbamoyl, N,N-dimethylcarbamoyl, morpholinocarbamoyl, or piperidinocarbamoyl group or the like), a sulfamoyl group (e.g., a sulfamoyl, N,N-dimethylsulfamoyl, morpholinosulfamoyl, or piperidinosulfamoyl group or the like), an aryl group having 30 or less carbon atoms (e.g., a phenyl, 4-chlorophenyl, 4-methylphenyl, or α-naphthyl group or the like), a substituted amino group (e.g., an amino, alkylamino, dialkylamino, arylamino, diarylamino, or acylamino group or the like), a substituted ureido group, a substituted phosphono group, a heterocyclic group, and so on. In the examples listed above, the carboxyl group, sulfo group, hydroxy group, and phosphono group may be in a salt state. In this case, examples of the cation constituting the salt include G⁺ and the like, which are described later.

Examples of the alkenyl group include a straight-chain alkenyl group, a branched alkenyl group, and a cyclic alkenyl group. The number of carbon atoms in the alkenyl group is preferably 2 to 30 and more preferably 2 to 20. The alkenyl group may be an alkenyl group having a substituent or an alkenyl group having no substituent. The range of the preferable number of carbon atoms in the alkenyl portion of the substituted alkenyl group is the same as in the alkenyl group.

Examples of the substituents of the substituted alkenyl groups include the same substituents as in the case of the substituted alkyl groups.

Examples of the alkynyl group include a straight-chain alkynyl group, a branched alkynyl group, and a cyclic alkynyl group. The number of carbon atoms in the alkynyl group is preferably 2 to 30 and more preferably 2 to 20. The alkynyl group may be an alkynyl group having a substituent or an alkynyl group having no substituent. The range of the preferable number of carbon atoms in the alkynyl portion of the substituted alkynyl group is the same as in the alkynyl group.

Examples of the substituents of the substituted alkynyl groups include the same substituents as in the case of the substituted alkyl groups.

Examples of the aralkyl group include a straight-chain aralkyl group, a branched aralkyl group, and a cyclic aralkyl group. The number of carbon atoms in the aralkyl group is preferably 7 to 35 and more preferably 7 to 25. The aralkyl group may be an aralkyl group having a substituent or an aralkyl group having no substituent. The range of the preferable number of carbon atoms in the aralkyl portion of the substituted aralkyl group is the same as in the aralkyl group.

Examples of the substituents of the substituted aralkyl groups include the same substituents as in the case of the substituted alkyl groups.

If Rₐ¹ to Rₐ⁴ each represents an aromatic alkyl group, examples of the aromatic group include an aryl group and a substituted aryl group. The number of carbon atoms in the aryl group is preferably 6 to 30 and more preferably 6 to 20. The range of the preferable number of carbon atoms in the aryl portion of the substituted aryl group is the same as in the aryl group. Examples of the aryl group include a phenyl group, an α-naphthyl group, β-naphthyl group and the like.

Examples of substituents of the substituted aryl group include the same substituents as in the case of the substituted alkyl groups.

If Rₐ¹ to Rₐ⁴ each represents a heterocyclic group, examples of the heterocyclic group include a heterocyclic group having a substituent and a heterocyclic group having no substituent. Examples of the substituent of the heterocyclic group having a substituent include the same substituents as the substituents in the case of Rₐ¹ to Rₐ⁴ representing substituted aryl groups.

Among the heterocyclic groups that can be represented by Rₐ¹ to Rₐ⁴, preferable are heterocyclic groups containing a nitrogen atom, sulfur atom or oxygen atom, such as a furan ring, a pyrrole ring, an imidazole ring, an oxazole ring, a thiazole ring, a pyridine ring and the like.

If Rₐ¹ to Rₐ⁴ each represents —Si(Rₐ⁵)(Rₐ⁶)—Rₐ⁷, Rₐ⁵, Rₐ⁶ and Rₐ⁷ each independently represents an aliphatic group or an aromatic group. The aliphatic group and the aromatic group have the same respective meanings as the aliphatic group and the aromatic group represented by Rₐ¹ to Rₐ⁴. The same applies to preferable examples thereof.

In the general formula (A), two or more of Rₐ¹, Rₐ², Rₐ³ and Rₐ⁴ may form a ring directly or via a substituent. In a case where a ring is formed, the ring is preferably any ring selected from the following rings (C1) to (C3). Among these rings, (C2) is preferable.

[chemical structure]

In the ring (C1), R_{b} represents any of the following bivalent groups.

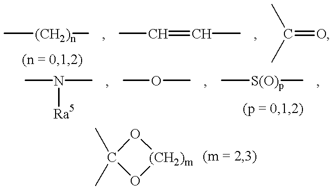

(Rₐ⁵ is H or a monovalent substituent)

Among the organoboron compounds represented by the general formula (A), an organoboron compound in which at least one of Rₐ¹ to Rₐ⁴ is an alkyl group is preferable; and a triarylalkyl-type organoboron compound in which one of Rₐ¹ to Rₐ⁴ is an alkyl is more preferable group and other three of Rₐ¹ to Rₐ⁴ are each an aryl group from the standpoint of raising sensitivity and enhancing storability.

In particular, a triarylalkyl-type organoboron compound whose aryl groups have an electron-withdrawing substituent is preferable. Among these compounds, more preferable is a compound in which the sum of Hammett (σ) values of the substituents (electron-withdrawing groups) on the three aryl groups is from +0.36 to +2.58.

As the electron-withdrawing group, a halogen atom or a trifluoromethyl group is preferable, and a fluorine atom or a chlorine atom is more preferable.

Examples of the aryl group having an electron-withdrawing substituent include a 3-fluorophenyl group, a 4-fluorophenyl group, a 2-fluorophenyl group, a 3-chlorophenyl group, a 4-chlorophenyl group, 3-trifluoromethylphenyl group, 4-trifluoromethylphenyl group, 3,5-difluorophenyl group, 4-bromophenyl group, 3,4-difluorophenyl group, 5-fluoro-2-methylphenyl group, 5-fluoro-4-methylphenyl group, 5-chloro-2-methylphenyl group, 5-chloro-4-methylphenyl group, and so on.

Specific examples of an anionic portion of the general formula (A) include tetramethyl borate, tetraethyl borate, tetrabutyl borate, triisobutylmethyl borate, di-n-butyl-di-t-butyl borate, tri-m-chlorophenyl-n-hexyl borate, triphenylmethyl borate, triphenylethyl borate, triphenylpropyl borate, triphenyl-n-butyl borate, trimesitylbutyl borate, tritolylisopropyl borate, triphenylbenzyl borate, tetra-m-fluorobenzyl borate, triphenylphenethyl borate, triphenyl-p-chlorobenzyl borate, triphenylethenylbutyl borate, di(α-naphthyl)-dipropyl borate, triphenylsilyltriphenyl borate, tritolylsilyltriphenyl borate, tri-n-butyl (dimethylphenylsilyl) borate, diphenyldihexyl borate, tri-m-fluorophenylhexyl borate, tri-(5-chloro-4-methylphenyl)hexyl borate, tri-m-fluorophenylcyclohexyl borate, tri-(5-fluoro-2-methylphenyl)hexyl borate, and so on.

In the general formula (A), G⁺ represents a group capable of forming a cation. In particular, preferable are an organo-cationic compound, a complex cation coordinated with a transition metal (e.g., compounds described in Japanese Patent No. 2791143 and the like), or a metallic cation (e.g., Na⁺, K⁺, Li⁺, Ag⁺Fe²⁺, Fe³⁺, Cu⁺, Cu²⁺, Zn²⁺, Al³⁺, ½ Ca²⁺, or the like).

Examples of the organo-cationic compound include a quaternary ammonium cation, a quaternary pyridinium cation, a quaternary quinolinium cation, a phosphonium cation, an iodonium cation, a sulfonium cation, a dye cation, and so on.

Examples of the quaternary ammonium cation include a tetraalkyl ammonium cation (e.g., a tetramethylammonium cation or a tetrabutylammonium cation), a tetraaryl ammonium cation (e.g., a tetraphenylammonium cation and the like). Examples of the quaternary pyridinium cation include an N-alkylpyridinium cation (e.g., an N-methylpyridinium cation), an N-arylpyridinium cation (e.g., an N-phenylpyridinium cation), an N-alkoxypyridinium cation (e.g., a 4-phenyl-N-methoxylpyridinium cation), an N-benzoylpyridinium cation and the like. Examples of the quaternary quinolinium cation include an N-alkylquinolinium cation (e.g., an N-methylquinolinium cation), an N-arylqunolinium cation (e.g., an N-phenylquinolinium cation) and the like. Examples of the phosphonium cation include a tetraarylphosphonium cation (e.g., a tetraphenylphosphonium cation) and the like. Examples of the iodonium cation include a diaryliodonium cation (e.g., a dipenyliodonium cation)and the like. Examples of the sulfonium cation include a triarylsulfonium cation (e.g., a triphenylsulfonium cation)and the like.

In addition, specific examples of G⁺ include compounds described in JP-A No. 9-188686, paragraphs [0020] to [0038] and the like.

In each of the above-listed cationic compounds (exemplary compounds), an alkyl group thereof is preferably an alkyl group having 1 to 30 carbon atoms, such as an unsubstituted alkyl group, e.g., a methyl, ethyl, propyl, isopropyl, butyl, or hexyl group or the like, or any of the aforementioned alkyl groups represented by Rₐ¹ to Rₐ⁴. Among these groups, an alkyl group having 1 to 12 carbon atoms is particularly preferable.

In each of the above-listed cationic compounds, an aryl group thereof is preferably, for example, a phenyl group, a halogen atom-substituted(e.g., chlorine atom-substituted) phenyl group, an alkyl-substituted(e.g., methyl-substituted)

phenyl group, or an alkoxy (e.g., methoxy)-substituted phenyl group.

Specific examples of the organoboron compounds represented by the general formula (A) include the compounds described in U.S. Pat. Nos. 3,567,453 and 4,343,891, JP-A Nos. 62-143044, 62-150242, 9-188684, 9-188685, 9-188686, and 9-188710, JP-B No.8-9643, JP-A No. 11-269210, and the following exemplary compounds. The organoboron compound may be used together with a radical generator that is described later. However, it should be noted that the organoboron compounds to be used in the present invention are not limited to these compounds.

[chemical structure]

In the photopolymerizable composition, the amount of the radical generator is preferably 0.01 to 20% by weight, more preferably 0.1 to 10% by weight, based on the content of the polymerizable compound having an ethylenically unsaturated bond. However, a preferable range is not limited to the above-mentioned ranges because preferable range varies depending on the kind of the polymerizable compound having an ethylenically unsaturated bond to be used with the radical generator.

(Other Components)

Depending on purpose, the photopolymerizable composition of the present invention may contain conventionally known additives appropriately selected as other components, such that these additives do not impair the effects of the present invention.

Examples of the other components include a photopolymerization initiator, an oxygen scavenger, a thermal polymerization inhibitor, an ultraviolet absorber, a fluorescent brightener, a chain-transfer agent, an antioxidant and the like, and precursors and the like thereof. The amounts of these additives are preferably 0.01 to 20% by weight, more preferably 0.2 to 15% by weight, and particularly preferably 0.5 to 10% by weight based on total weight of the photopolymerizable composition.

Specific examples of the additives, such as chain-transfer agents and antioxidants, include those described in, for example, JP-A No. 10-45816, paragraphs [0135]-[0141], JP-A No. 9-188686, paragraphs [0087]-[0096], JP-A No. 10-182621, paragraphs [0079]-[0118], JP-A No. 9-95487, paragraphs [0080]-[0089], and the like. In addition, specific examples of the additives include the compounds described in JP-A Nos. 1-13140, 1-13141, 1-13143, 1-13144, 1-17048, 1-229003, 1-298348, 10-138638, 11-269210, and 2-187762 and the like.

The photopolymerizable composition of the present invention may also contain a binder. In particular, use of the binder is advantageous when the photopolymerizable composition is a liquid or viscous substance.

The content of the binder is preferably 5 to 95% by weight, more preferably 10 to 90% by weight, and particularly preferably 15 to 85% by weight based on the total weight of solid components.

Selection of the binder is made depending on field of application and characteristics required for that field of application, such as capability to develop images in a water- or organic solvent-based system, adhesion to substrates, and sensitivity to oxygen.

A polymer having a molecular weight of about 5,000 to 2,000,000, preferably 10,000 to 1,000,000, is desirable as the binder. Examples of the polymer include homopolymers and copolymers of acrylates and methacrylates (e.g., a copolymer of methyl methacrylate/ethyl acrylate/methacrylic acid, a poly(alkyl methacrylate), a poly(alkyl acrylate) and the like), cellulose esters and cellulose ethers (e.g., cellulose acetate, cellulose acetobutylate, methyl cellulose, ethyl cellulose and the like), polyvinyl butyral, polyvinyl formal, cyclized rubber, polyethers (e.g., polyethylene oxide, polypropylene oxide, and polytetrahydrofuran), polystyrene, polycarbonate, polyurethane, chlorinated polyolefin, polyvinyl chloride, a vinyl chloride/vinylidene copolymer, a vinylidene chloride/acrylonitrile copolymer, methyl methacrylate, vinyl acetate, polyvinyl acetate, copoly(ethylene/vinyl acetate), polycaprolactam, poly(hexamethylene adipamide), polyesters (e.g., poly(ethylene glycol terephthalate) and poly(hexamethylene glycol succinate) and the like), polyamide, polyurea, and so on.

Further examples include water-soluble polymers such as gelatins, (modified)polyvinyl alcohol, polyvinylpyrrolidone, hydrolysis products of styrene/maleic acid copolymers, sodium polystyenesulfonate, sodium alginate and the like. Furthermore, latices such as styrene/butadiene rubber latex, acrylonitrile/butadiene rubber latex, and methyl acrylate/butadiene rubber latex may be used.

An unsaturated compound can also be used in a mixture with a non-photopolymerizable, film-forming component. An example of the unsaturated compound is a physically dried polymer or a polymer solution in an organic solvent. Examples include nitrocellulose and cellulose acetobutylate. The compound may be a chemically and/or thermally hardenable (i.e., thermosetting) resin such as a polyisocyanate, a polyepoxide, a melamine resin, or a polyimide precursor. The use of a thermosetting resin in the photopolymerizable composition is important for a system known as a hybrid system in which the composition undergoes photopolymerization in a first stage and thereafter crosslinking by a thermal post-treatment in a second stage.

A binder having a polymerizable group can also be used.

Examples of other additives include the additives described in JP-A No. 11-269210.

A light source that is usable when image-wise exposure is carried out can be selected appropriately from known light sources whose emission wavelengths are in the visible-to-infrared region. Among the light sources, preferable is a light source whose maximum absorption wavelength is 300 to 1000 nm and more preferable, in view of simple and small-sized apparatus and low costs, is a blue, green, or red (semiconductor) laser source or LED. In order to obtain a higher sensitivity, it is preferable to select a light source whose wavelength matches an absorption wavelength of a light-absorbing material such as the spectral sensitizing dye or the like.

On the other hand, it is preferable that a light source that is usable for decolorization of the photopolymerizable composition and the below-descrebed recording material is selected from light sources whose wavelengths match the absorption wavelength of the photopolymerizable composition. Specific examples of light sources suited for this purpose are wide-ranging and include a mercury lamp, an ultrahigh-pressure mercury lamp, an electrodeless discharge type mercury lamp, a xenon lamp, a tungsten lamp, a metal halide lamp, a (semiconductor) laser light source, an LED, a fluorescent lamp and the like.

As described above, use of a compound represented by the general formulae (1) to (3) as a spectral sensitizing dye makes it possible to form images with a high-level of sensitivity not only using ultraviolet light but also using visible-to-infrared light, and to obtain images without remnant colors caused by dye components, because the compound itself has excellent decolorization property.

<Recording Material>

The recording material of the present invention includes a support having disposed thereon a recording layer containing at least a color-forming component A, a color-forming component B having a site which reacts with the color-forming component A and causes the color-forming component A to develop color, and the photopolymerizable composition of the present invention described above. In addition, as necessary, the recording material of the present invention may have other layers such as an undercoat layer, an intermediate layer, a light-absorbing layer, a protective layer, and a back coat layer.

The basic construction mode of the recording material of the present invention is not particularly limited and the recording material of the present invention may be constructed according to purposes.

An example of the basic mode, in which the recording material of the present invention, having the color-forming component A enclosed in heat-responsive microcapsules, is used as a positive-type photo- and heat-sensitive recording material for image formation, is described below.

That is, when the positive-type recording material of the present mode is irradiated with light image-wisely, a radical is generated from the radical generator contained in an irradiated region of the photopolymerizable composition so that the radical thus generated initiates the polymerization reaction of the polymerizable compound and the polymerizable compound hardens. As a result, the polymerizable composition is fixed in position and a latent image is formed. The microcapsules are impermeable to substances at room temperature and therefore the color-forming component A enclosed in the microcapsules is out of contact with the color-forming component B, which has in the molecule thereof a site which reacts with the color-forming component A to thereby cause the color-forming component A to develop color. Accordingly, at room temperature, the microcapsules are in a state that does not develop color.

At a later stage, when heat is applied to the entire face of the photo- and heat-sensitive recording material, the microcapsules are made permeable to substances and therefore the color-forming component B in a non-irradiated region penetrates into the microcapsules to react with the color-forming component A (and/or the color-forming component A is released out of the microcapsules) and color is developed only in the non-irradiated region. Meanwhile, in the irradiated region, since the photopolymerizable composition is in a hardened and fixed state because of by the polymerization reaction, the color-forming components A and B are immobilized and out of contact with each other and therefore color is not developed in the irradiated region. After that, when the entire face of the photo- and heat-sensitive recording material is exposed to light, the region that has not been polymerized undergoes polymerization (i.e., fixation) and the dye component contained in the photopolymerizable composition can be decolorized.

Alternatively, the recording material of the present invention may be a recording material according to the following modes (i.e., a first and second mode) and the image forming method may be selected accordingly for each mode.

That is, in a recording material according to the first mode, at least one of the polymerizable compounds contained in the polymerizable composition is the color-forming component B itself and the recording layer contains at least the color-forming component A and the photopolymerizable composition of the present invention, which contains the color-forming component B capable of causing the color-forming component A to develop color. If the positive-type, photo- and heat-sensitive recording material of the above-described basic mode is taken as an example, the color-forming component B has a site which causes the color-forming component A to develop color, and an ethylenically unsaturated bond as stated above. When the recording material is irradiated with light image-wisely, the color-forming component B starts the polymerization reaction and hardens. As a result, the color-forming component B is fixed in place site and a latent image is formed. Therefore, in the irradiated region, the color-forming component B is immobilized and is out of contact with the color-forming component A. Accordingly, the color-forming component B does not develop color in the irradiated region.

In a recording material according to the second mode of the present invention, the recording layer thereof contains at least a color-forming component A, a color-forming component B which reacts with the color-forming component A and causes the color-forming component A to develop color, and the photopolymerizable composition of the present invention as described above. The polymerizable compound, which is contained in the photopolymerizable composition and has an ethylenically unsaturated bond (i.e., is a polymerizable compound), is a color formation-inhibiting compound having in the molecule thereof a site which inhibits the reaction between the color-forming component A and the color-forming component B (i.e., a reaction-inhibiting site).

An example of image formation, in which the recording material of the second mode is a negative-type photo- and heat-sensitive recording material having the color-forming component A enclosed in heat-responsive microcapsules, is described below.

In the negative-type photo- and heat-sensitive recording material according to the present mode, the microcapsules are impermeable to substances at room temperature and therefore the color-forming component A is out of contact with the color-forming component B, as in the first mode. Accordingly, color is not developed at room temperature. When the recording material is irradiated with light image-wise, the polymerizable compound in the irradiated region starts the polymerization reaction and hardens. As a result, the polymerizable compound is fixed in place and a latent image is formed. After that, when heat is applied to the entire face of the photo- and heat-sensitive recording material, the microcapsules become permeable to substances and thus the color-forming component B penetrates into the microcapsules (and/or the color-forming component A is released out of the microcapsules). At the same time, in the non-irradiated region, the polymerizable compound, which acts as a color formation-inhibiting compound, penetrates into the microcapsules and the color developing reaction between the color-forming components A and B is inhibited. As a result, the non-irradiated region is maintained in a non-colored state. On the other hand, in the irradiated region, since the photopolymerizable compound (i.e., the color formation-inhibiting compound) was fixed in position by the polymerization reaction, the photopolymerizable compound is not involved in the reaction between the color-forming components A and B, and the color developing reaction proceeds. In this way, color is developed only in the irradiated region. After that, when the entire face of the photo- and heat-sensitive recording material is exposed to light, the dye component contained in the photopolymerizable composition can be decolorized.

The same light sources as those usable for exposure of the photopolymerizable composition of the present invention can be used as light sources for image formation with the recording material of the present invention.

The constituent components to be used in the recording material of the present invention are explained below.

(Photopolymerizable Composition)

The photopolymerizable composition comprises (1) a polymerizable compound having an ethylenically unsaturated bond (i.e., a polymerizable compound), (2) an organic dye that can be decolorized (i.e., a spectral sensitizing dye), (3) a radical generator capable of interacting with the dye to generate a radical, and optionally (4) other components. In the recording material of the present invention, the photopolymerizable composition of the present invention as described above is used.

When the photopolymerizable composition is irradiated with light, the spectral sensitizing dye absorbs the light and interacts with the radical generator to generate a radical. The radical thus generated causes radical polymerization of the polymerizable compound to thereby harden the polymerizable compound and form an image.

The details of the polymerizable compound are as described previously. Several kinds of the polymerizable compound may be incorporated in the photopolymerizable composition. In the recording material according to the first mode, at least one of the polymerizable compounds used may be the color-forming component B having a site capable of causing the color-forming component A to develop color, as well as being a color-forming component having in the molecule thereof an ethylenically unsaturated bond (i.e., a polymerizable group), as described later.

On the other hand, in the recording material according to the second mode, the polymerizable compound may function also as a color formation-inhibiting compound, and a polymerizable compound having in the molecule thereof the color-forming component A and a site which inhibits the color developing reaction between the color-forming component A and the color-forming component B is used.

These polymerizable compounds are described later together with the color-forming components (A and B) to be incorporated in the recording layer.

The content of the photopolymerizable composition in the recording layer is preferably 0.1 to 50 g/m², and more preferably 1 to 30 g/m².

(Color-forming Components)

In the recording material of the present invention, the recording layer contains the color-forming component A and color-forming component B as a color-forming source together with the photopolymerizable composition. In the case of the recording material according to the first mode, the recording layer contains the color-forming component A together with the photopolymerizable composition, and the color-forming component B, serving as the polymerizable compound contained in the photopolymerizable composition, reacts with the color-forming component A to develop color.

Examples of the combination of the color-forming component A and the color-forming component B, serving as a color-forming source for constituting image portions, include the following combinations (i) to (xix). In the following combinations, the color-forming component A is listed first and the color-forming component B is listed second.

(i) A combination of an electron-donating dye precursor and an electron-accepting compound.

(ii) A combination of a diazo compound and a coupling component (hereinafter referred to as “a coupler compound” upon occasion).

(iii) A combination of a metal salt of an organic acid, such as silver behenate or silver stearate or the like, and a reducing agent such as protocatechinic acid, spiroindan, hydroquinone or the like.

(iv) A combination of an iron salt of a long-chain fatty acid, such as ferric stearate or ferric myristate or the like, and a phenol such as tannic acid, gallic acid, or ammonium salicylate or the like.

(v) A combination of a heavy metal salt of an organic acid, such as a nickel, cobalt, lead, copper, iron, mercury, or silver salt of acetic acid, stearic acid, palmitic acid or the like, and a sulfide of an alkali metal or an alkaline earth metal, such as calcium sulfide, strontium sulfide, potassium sulfide or the like; or a combination of the above-described heavy metal salt of an organic acid and an organic chelating agent such as s-diphenylcarbazide, diphenylcarbazone or the like.

(vi) A combination of a heavy metal sulfate, such as a silver, lead, mercury, sodium or the like salt of sulfuric acid, and a sulfur compound such as sodium tetrathionate, sodium thiosulfate, thiourea or the like.

(vii) A combination of a ferric salt of a fatty acid, such as ferric stearate or the like, and an aromatic polyhydroxy compound such as 3,4-hydroxytetraphenyl methane or the like.

(viii) A combination of a metal salt of an organic acid, such as silver oxalate or mercury oxalate or the like, and an organic polyhydroxy compound such as polyhydroxy alcohol, glycerin, glycol or the like.

(ix) A combination of a ferric salt of a fatty acid, such as ferric pelargonate or ferric laurate or the like, and a thiocesylcarbamide or isothiocesylcarbamide derivative.

(x) A combination of a lead salt of an organic acid, such as lead capronate, lead pelargonate, lead behenate or the like, and a thiourea derivative such as ethylene thiourea or N-dodecyl thiourea or the like.

(xi) A combination of a heavy metal salt of a higher fatty acid, such as ferric stearate or copper stearate or the like, and zinc dialkyldithiocarbamate;

(xii) A combination capable of forming an oxazine dye, such as a combination of resorcinol and a nitroso compound.

(xiii) A combination of a formazan compound and a reducing agent and/or a metal salt.

(xiv) A combination of a protected dye (or leuco dye) precursor and a deblocking agent.

(xv) A combination of an oxidation-type color-forming agent and an oxidizing agent.

(xvi) A combination of a phthalonitrile and a diiminoisoindoline (i.e., a combination that forms phthalocyanine).

(xvii) A combination of an isocyanate and a diiminoisoindoline (i.e., a combination that forms a coloring pigment).

(xviii) A combination of a pigment precursor and an acid or base (i.e., a combination that forms a pigment).

(xix) A combination of a precursor in the oxidized form of a p-phenylene diamine or p-aminophenol derivative and a coupling component (i.e., a coupler compound).

Among the above-listed two-component combination color-forming sources, preferable are (i) the combination of an electron-donating dye precursor and an electron-accepting compound; (ii) the combination of a diazo compound and a coupling component; (xiv) the combination of a protected dye (or leuco dye) precursor and a deblocking agent; and (xix) the combination of a precursor in the oxidized form of a p-phenylene diamine or p-aminophenol derivative and a coupling component. That is, an electron-donating dye precursor, a diazo compound, a dye precursor, or a precursor in oxidized form is preferable as the color-forming component A, while an electron-accepting compound, a coupler compound, or a deblocking agent is preferable as the color-forming component B.

If an electron-donating colorless dye precursor is to be used as the color-forming component A, examples of the electron-donating colorless dye precursor include a phthalide-based compound, a fluoran-based compound, a phenothiazine-based compound, an indolylphthalide-based compound, a leucoauramine-based compound, a rhodamine lactam-based compound, a triphenylmethane-based compound, a triazene-based compound, a spriopyran-based compound, a pyridine-based compound, a pyrazine-based compound, a fluorene-based compound, and so on, which are all known in heat-sensitive paper, pressure-sensitive paper, or the like.

Examples of the phthalide-based compound include the compounds described in, for example, re-issued U.S. Pat. No. 23,024, and U.S. Pat. Nos. 3,491,111, 3,491,112, 3,491,116, and 3,509,174. Specific examples include 3,3-bis(p-dimethylaminophenyl)-6-dimethylaminophthalide, 3,3-bis(p-diethylaminophenyl)phthalide, 3,3-bis(2-methyl-1-octylindole-3-yl)phthalide, 3-(4-dipropylamino-2-acetylaminophenyl)-3-(2-methyl-l-octylindole-3-yl)-4-azaphthalide, 3-(4-diethylamino-2-ethoxyphenyl)-3-(2-methyl-1-octylindole-3-yl)phthalide, 3-(4-diethylamino-2-ethoxyphenyl)-3-(2-methyl-1-octylindole-3-yl)-4-azaphthalide, 3-(4-diethylamino-2-methylphenyl)-3-(1-ethyl-2-methylindole-3-yl)-4-azaphthalide, 3,3-bis(4-diethylamino-2-butyloxyphenyl)-4-azaphthalide, 3-(4-diethylamino-2-butyloxyphenyl)-3-(2-methyl-1-pentylindole-3-yl)-4-azaphthalide, and so on.

Examples of the fluoran-based compound include the compounds described in, for example, U.S. Pat. Nos. 3,624,107, 3,627,787, 3,641,011, 3,462,828, 3,681,390, 3,920,510, and 3,959,571. Specific examples include 2-anilino-3-methyl-6-diethylaminofluoran, 2-anilino-3-methyl-6-dibutylaminofluoran, 2-anilino-3-methyl-6-N-ethyl-N-isoamylaminofluoran, 2-anilino-3-methyl-6-N-methyl-N-cyclohexylaminofluoran, 2-anilino-3-methyl-6-N-ethyl-N-isobutylaminofluoran, 2-anilino-6-dibutylaminofluoran, 2-anilino-3-methyl-6-N-methyl-N-tetrahydrofurfurylaminofluoran, and so on.

Examples of the thiazine-based compound include benzoyl leucomethylene blue, p-nitrobenzyl leucomethylene blue, and so on.

Examples of the leucoauramine-based compounds include 4,4′-bis-dimethylaminobenzhydrin benzyl ether, N-halophenyl-leucoauramine, N-2,4,5-trichlorophenyl leucoauramine, and so on.

Examples of the rhodamine lactam-based compound include rhodamine-B-anilinolactam, rhodamine-(p-nitrino)lactam, and so on.

Examples of the spiropyran-based compound include the compounds described in, for example, U.S. Pat. No. 3,971,808. Specific examples include 3-methyl-spiro-dinaphthopyran, 3-ethyl-spiro-dinaphthopyran, 3,3′-dichloro-spiro-dinaphthopyran, 3-benzylspiro-dinaphthopyran, 3-methyl-naphto-(3-methoxybenzo)spiropyran, 3-propyl-spiro-dibenzopyran, and so on.

Examples of the pyridine-based compound and pyrazine-based compound include the compounds described in, for example, U.S. Pat. Nos. 3,775,424, 3,853,869, and 4,246,318.

Examples of the fluorene-based compound include the compounds described in, for example, Japanese Patent Application No. 61-240989.

As the dye precursors, which develop cyan, magenta, and yellow colors, dye precursors described in, for example, U.S. Pat. No. 4,800,149 can be used.

Further, as an electron-donating dye precursor for developing yellow color, dye precursors described in, for example, U.S. Pat. Nos. 4,800,148 and 5,126,233, and JP-B No. 7-88105 can be used. As an electron-donating dye precursor for developing cyan color, dye precursors described in, for example, JP-A No. 63-53542 can be used.

When the electron-donating dye precursor is used, an electron-accepting compound is used as the color-forming component B that causes the electron-donating dye precursor to develop color.

Examples of the electron-accepting compound include a phenol derivative, a salicylic acid derivative, a metal salt of an aromatic carboxylic acid, acid clay, bentonite, novolak resin, metal-treated novolak resin, a metal complex, and the like, which are known in heat-sensitive paper, pressure-sensitive paper, and the like. Specific examples are described in, for example, JP-B Nos. 40-9309 and 45-14039, JP-A Nos. 52-140483, 48-51510,57-210886, 58-87089, 59-11286, 60-176795, and 61-95988 and the like.

Among the substances listed above, examples of the phenol derivative include 2,2-bis(4-hydroxyphenyl)propane, 1,1-bis(3-chloro-4-hydroxyphenyl)cyclohexane, 4-hydroxyphenyl-4′-isopropyloxyphenyl sulfone, bis(3-allyl-hydroxyphenyl)sulfone, α,α′-bis(4-hydroxyphenyl)-1,4-diisopropylbenzene, benzyl p-hydroxybenzoate, and so on.

Examples of the salicylic acid derivative include 4-pentadecylsalicylic acid, 3,5-di(α-methylbenzyl)salicylic acid, 3,5-di(tert-octyl)salicylic acid, 5-octadecylsalicylic acid, 5-α-(p-α-methylbenzylphenyl)ethylsalicylic acid, 3-α-methylbenzyl-5-tert-octylsalicylic acid, 5-tetradecylsalicylic acid, 4-hexyloxysalicylic acid, 4-cyclohexyloxysalicylic acid, 4-decyloxysalicylic acid, 4-dodecyloxysalicylic acid, 4-pentadecyloxysalicylic acid, 4-octadecyloxysalicylic acid and the like, zinc salts of these acids, aluminum salts of these acids, calcium salts of these acids, copper salts of these acids, and so on.

In the recording material according to the first mode, the color-forming component B also functions as a polymerizable compound having an ethylenically unsaturated bond. Accordingly, at least one of the polymerizable compounds of the recording material according to the first mode is an electron-accepting compound having in the molecule thereof an electron-accepting group and an ethylenically unsaturated bond (hereinafter referred to as “polymerizable group”).

Examples of such color-forming component B include compounds that can be synthesized with reference to, for example, 3-halo-4-hydroxybenzoic acid described in JP-A No. 4-226455, methacryloxyethyl esters and acryloxyethyl esters of hydroxy-bearing benzoic acid which are described in JP-A No. 63-173682, esters of hydroxy-bearing benzoic acid and hydroxymethylstyrene which are described in JP-A Nos. 59-83693, 60-141587, and 62-99190, hydroxystyrene described in European Patent No. 29323, N-vinylimidazole complexes of zinc halides described in JP-A Nos. 62-167077 and 62-167078, and electron-accepting compounds described in JP-A No. 63-317558, and the like.

Among these compounds having in the molecule thereof an electron-accepting group and a polymerizable group, preferable is a 3-halo-4-hydroxybenzoic acid represented by the following general formula:

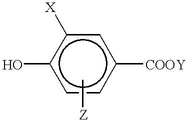

In the formula above, X is a halogen atom and preferably a chlorine atom. Y is a monovalent group having a polymerizable ethenyl group, preferably an aralkyl group having a vinyl group, an acryloyloxyalkyl group, or a methacryloyloxyalkyl group, and more preferably an acryloyloxyalkyl group having 5 to 11 carbon atoms, or a methacryloyloxyalkyl group having 6 to 12 carbon atoms. Z represents a hydrogen atom, an alkyl group, or an alkoxy group.

Examples of the 3-halo-4-hydroxybenzoic acid include 3-chloro-4-hydroxybenzoic acid vinylphenethyl ester, 3-chloro-4-hydroxybenzoic acid vinylphenylpropyl ester, 3-chloro-4-hydroxybenzoic acid 2-acryloyloxyethyl ester, 3-chloro-4-hydroxybenzoic acid 2-methacryloyloxyethyl ester, 3-chloro-4-hydroxybenzoic acid 2-acryloyloxypropyl ester, 3 chloro-4-hydroxybenzoic acid 2-methacryloyloxypropyl ester, 3-chloro-4-hydroxybenzoic acid 3-acryloyloxypropyl ester, 3-chloro-4-hydroxybenzoic acid 3-methacryloyloxypropyl ester, 3-chloro-4-hydroxybenzoic acid 4-acryloyloxybutyl ester, 3-chloro-4-hydroxybenzoic acid 4-methacryloyloxybutyl ester, 3-chloro-4-hydroxybenzoic acid 2-acryloyloxyethyl ester, 3-chloro-4-hydroxybenzoic acid 5-acryloyloxypentyl ester, 3-chloro-4-hydroxybenzoic acid 5-methacryloyloxypentyl ester, 3-chloro-4-hydroxybenzoic acid 6-acryloyloxyhexyl ester, 3-chloro-4-hydroxybenzoic acid 6-methacryloyloxyhexyl ester, 3-chloro-4-hydroxybenzoic acid 8-acryloyloxyoctyl ester, 3-chloro-4-hydroxybenzoic acid 8-methacryloyloxyoctyl ester, and so on.

In addition, the following are also suitable. Styrenesulfonylaminosalicylic acid, vinylbenzyloxyphthalic acid, zinc β-methacryloxyethoxysalicylate, zinc β-acryloxyethoxysalicylate, vinyloxyethyl oxybenzoate, β-methacryloxyethyl orsellinate, β-acryloxyethyl orsellinate, β-methacryloxyethoxyphenol, β-acryloxyethoxyphenol, β-methacryloxyethyl-β-resorcinate, β-acryloxyethyl-β-resorcinate, hydroxystyrenesulfonic acid-N-ethylamide, β-methacryloxypropyl-p-hydroxybenzoate, β-acryloxypropyl-p-hydroxybenzoate, methacryloxymethylphenol, acryloxymethylphenol, methacrylamidepropanesulfonic acid, acrylamidepropanesulfonic acid, β-methacryloxyethoxy-dihydroxybenzene, β-acryloxyethoxy-dihydroxybenzene, γ-styrenesulfonyloxy-β-methacryloxypropanecarboxylic acid, γ-acryloxypropyl-α-hydroxyethyloxysalicylic acid, β-hydroxyethoxylphenol, β-methacryloxyethyl-p-hydroxycinnamate, α-acryloxyethyl-p-hydroxycinnamate, 3,5-distyrenesulfonic acidamidephenol, methacryloxyethoxyphthalic acid, acryloxyethoxyphthalic acid, methacrylic acid, acrylic acid, methacryloxyethoxyhydroxynaphthoic acid, acryloxyethoxyhydroxynaphthoic acid, 3-β-hydroxyethoxylphenol, β-methacryloxyethylphenol-p-hydroxybenzoate, β-acryloxyethyl-p-hydroxybenzoate, β′-methacryloxyethyl-β-resorcinate, β-methacryloxyethyloxycarbonylhydroxybenzoic acid, β-acryloxyethyloxycarbonylhydroxybenzoic acid, N,N′-di-β-methacryloxyethylaminosalicylic acid, N,N′-di-β-acryloxyethylaminosalicylic acid, N,N′-di-β-methacryloxyethylaminosulfonylsalicylic acid, N,N′-di-β-acryloxyethylaminosulfonylsalicylic acid, and metal salts (e.g., zinc salts and the like) thereof and the like.

If an electron-donating dye precursor is used as the color-forming component A and an electron-accepting compound is used as the color-forming component B, the content of the electron-donating dye precursor in the recording layer is preferably 0.05 to 5 g/m², and more preferably 0.1 to 3 g/m².

The amount to be used of the electron-accepting compound is preferably 0.5 to 20 parts by weight, more preferably 3 to 10 parts by weight, for 1 part by weight of the electron-donating colorless dye. If the amount is less than 0.5 parts by weight, sufficient density of developed color may not be obtained, and if the amount exceeds 20 parts by weight, sensitivity may drop or coatability may become inferior.

If a diazo compound is used as the color-forming component A, it is preferable to use a compound represented by the following formula:

Ar—N⁺₂.Y⁻

where Ar represents an aromatic group and Y⁻ represents an acid anion.

In the above formula, Ar represents a substituted or unsubstituted aryl group. Examples of a substituent include an alkyl group, an alkoxy group, an alkylthio group, an aryl group, an aryloxy group, an arylthio group, an acyl group, an alkoxycarbonyl group, a carbamoyl group, a carboamide group, a sulfonyl group, a sulfamoyl group, a sulfonamide group, a ureido group, a halogen group, an amino group, a heterocyclic group, and so on. These substituents may be further substituted.

The aryl group is preferably an aryl group having 6 to 30 carbon atoms. Examples of the aryl group include a phenyl group, a 2-methylphenyl group, a 2-chlorophenyl group, a 2-methoxyphenyl group, a 2-butoxyphenyl group, a 2-(2-ethylhexyloxy)phenyl group, a 2-octyloxyphenyl group, a 3-(2,4-di-t-pentylphenoxyethoxy)phenyl group, a 4-chlorophenyl group, a 2,5-dichlorophenyl group, a 2,4,6-trimethylphenyl group, a 3-chlorophenyl group, a 3-methylphenyl group, a 3-methoxyphenyl group, a 3-butoxyphenyl group, a 3-cyanophenyl group, a 3-(2-ethylhexyloxy)phenyl group, a 3,4-dichlorophenyl group, a 3,5-dichlorophenyl group, a 3,4-dimethoxyphenyl group, a 3-(dibutylaminocarbonylmethoxy)phenyl group, a 4-cyanophenyl group, a 4-methylphenyl group, a 4-methoxyphenyl group, a 4-butoxyphenyl group, a 4-(2-ethylhexyloxy)phenyl group, a 4-benzylphenyl group, a 4-aminosulfonylphenyl group, a 4-N,N-dibutylaminosulfonylphenyl group, a 4-ethoxycarbonylphenyl group, a 4-(2-ethylhexylcarbonyl)phenyl group, a 4-fluorophenyl group, a 3-acetylphenyl group, a 2-acetylaminophenyl group, a 4-(4-chlorophenylthio)phenyl group, a 4-(4-methylphenyl)thio-2,5-butoxyphenyl group, a 4-(N-benzyl-N-methylamino)-2-dodecyloxycarbonylphenyl group, and so on.

These groups may be further substituted by an alkyloxy group, an alkylthio group, a substituted phenyl group, a cyano group, a substituted amino group, a halogen atom, a heterocyclic group, or the like.

Examples of diazo compounds that can be suitably used as the color-forming component A include the diazo compounds listed in JP-A No. 7-276808, paragraphs 44 to 49. It should be noted, however, that, in the present invention, the diazo compounds are not limited to these compounds.

From the standpoint of effect, a maximum absorption wavelength λₘₐₓ of the diazo compound is preferably 450 nm or less and more preferably 290 to 440 nm. In addition, it is desirable that the diazo compound has 12 or more carbon atoms and has a solubility in water of 1% or less and a solubility in ethyl acetate of 5% or more.

A diazo compound to serve as the color-forming component A may be used singly or in a combination of two or more kinds.

If a diazo compound as described above is used, a coupler compound (having no polymerizable group) or a coupler compound having a polymerizable group is used as the color-forming component B.

Each of the above-mentioned coupler compounds can undergo a coupling reaction with the diazo compound to form a dye in a basic environment and/or a neutral environment. According to purposes, such as color adjustment, plural kinds of coupler compound can be used in combination.

Examples of the coupler compound having a polymerizable group include a so-called active methylene compound having a methylene group adjacent to a carbonyl group, a phenol derivative, a naphthol derivative, an azole derivative, a heterocycle-condensed azole derivative and the like. These coupler compounds are appropriately selected so as to meet the purposes of the present invention.

As a coupler skeletal compound (coupler) in the coupler compound having the polymerizable group, preferably used are a so-called active methylene compound having a methylene group adjacent to a carbonyl group, a phenol derivative, a naphthol derivative, an azole derivative, a heterocycle-condensed azole derivative and the like. Specific examples thereof include resorcinol, phloroglucin, 2,3-dihydroxynaphthalene, sodium 2,3-dihydroxynaphthalene-6-sulfonate, 1-hydroxy-2-naphthoic acid morpholinopropylamide, sodium 2-hydroxy-3-naphthalenesulfonate, 2-hydroxy-3-naphthalenesulfonic acid anilide, 2-hydroxy-3-naphthalenesulfonic acid morpholinopropylamide, 2-hydroxy-3-naphthalenesulfonic acid-2-ethylhexyloxypropylamide, 2-hydroxy-3-naphthalenesulfonic acid-2-ethylhexylamide, 5-acetamido-1-naphthol, sodium 1-hydroxy-8-acetamidonaphthalene-3,6-disulfonate, 1-hydroxy-8-acetamidonaphthalene-3,6-disulfonic acid dianilide, 1,5-dihydroxynaphthalene, 2-hydroxy-3-naphthoic acid morpholinopropylamide, 2-hydroxy-3-naphthoic acid octylamide, 2-hydroxy-3-naphthoic acid anilide, 5,5-dimethyl-1,3-cyclohexanedione, 1,3-cyclopentanedione, 5-(2-n-tetradecyloxyphenyl)-1,3-cyclohexanedione, 5-phenyl-4-methoxycarbonyl-1,3-cyclohexanedione, 5-(2,5-di-n-octyloxyphenyl)-1,3-cyclohexanedione, N,N′-dicyclohexylbarbituric acid, N,N′-di-n-dodecylbarbituric acid, N-n-octyl-N′-n-octadecylbarbituric acid, N-phenyl-N′-(2,5-di-n-octyloxyphenyl)barbituric acid, N,N′-bis(octadecyloxycarbonylmethyl)barbituric acid, 1-phenyl-3-methyl-5-pyrazolone, 1-(2,4,6-trichlorophenyl)-3-anilino-5-pyrazolone, 1-(2,4,6-trichlorophenyl)-3-benzamido-5-pyrazolone, 6-hydroxy-4-methyl-3-cyano-1-(2-ethylhexyl)-2-pyridone, 2,4-bis(benzoylacetamido)toluene, 1,3-bis(pivaloylacetamidomethyl)benzene, benzoylacetonitrile, thenoylacetonitrile, acetoacetanilide, benzoylacetanilide, pivalolylacetanilide, 2-chloro-5-(N-n-butylsulfamoyl)-1-pivaloylacetamidobenzene, 1-(2-ethylhexyloxypropyl)-3-cyano-4-methyl-6-hydroxy-1,2-dihydropyridine-2-one, 1-(dodecyloxypropyl)-3-acetyl-4-methyl-6-hydroxy-1,2-dihydropyridine-2-one, 1-(4-n-octyloxyphenyl)-3-tert-butyl-5-aminopyrazole and so on.

For details of coupler compounds, reference can be made to those described in, for example, JP-A Nos. 4-201483, 7-223367, 7-223368, 7-323660 5-278608, 5-297024, 6-18669, 6-18670, 7-316280, 9-216468, 9-216469, 9-319025, 10-035113, 10-193801, and 10-264532.

The coupler compound undergoes a coupling reaction with a diazo compound to form a dye in a basic environment and/or a neutral environment. According to purposes, such as color adjustment, plural kinds of coupler compound can be used in combination.

Specific examples of the coupler having a polymerizable group are given below. It should be noted that, in the present invention, the couplers are not limited to these examples.

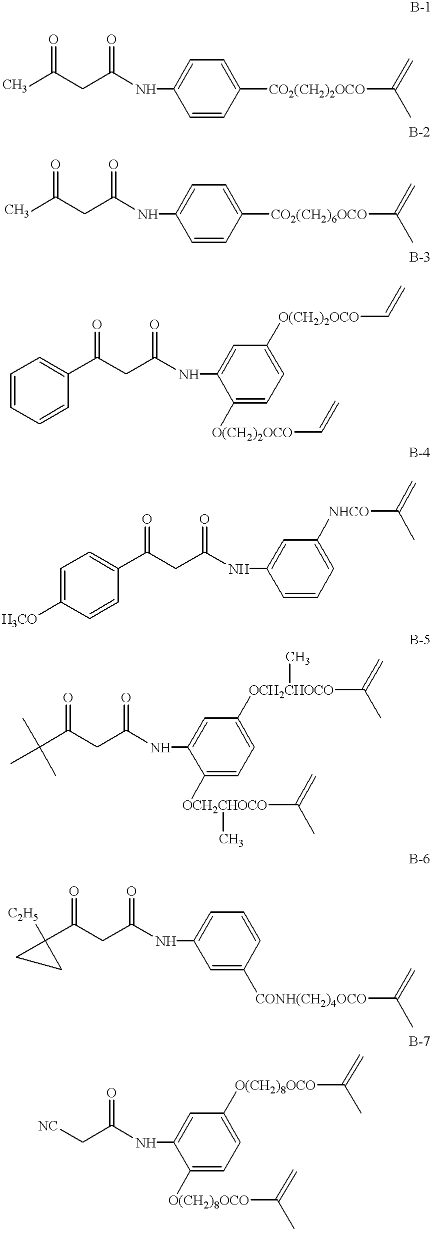

Examples of the coupler compound having no polymerizable group include the compounds listed as coupler skeletal compounds examples for the coupler compound having the polymerizable group.

If the diazo compound is to be used as the color-forming component A and the coupler is to be used as the color-forming component B, the content of the diazo compound in the recording layer is preferably 0.02 to 5.0 g/m², and more preferably 0.05 to 3.0 g/m².

If the content is less than 0.02 g/m², sufficient density of developed color may not be obtained, and if the content exceeds 5.0 g/m², coatability of a coating liquid may become inferior.

The amount to be used of the coupler compound is preferably 0.5 to 20 parts by weight, more preferably 1 to 10 parts by weight, for 1 part by weight of the diazo compound. If the amount is less than 0.5 parts by weight, sufficient density of developed color may not be obtained, and, if the amount exceeds 20 parts by weight, coatability may become inferior.

The coupler compound to be used as the color-forming component B can be used as a dispersion of solid particles prepared by adding other components and a water-soluble polymer to the coupler compound and dispersing in a sand mill or the like. The coupler compound can also be used as an emulsion prepared by emulsifying the coupler compound in the presence of a suitable emulsifying aid. The method for preparing the dispersion of solid particles and the emulsifying method are not particularly limited, and methods hitherto known can be employed. Details of these methods are described in JP-A Nos. 59-190886, 2-141279, and 7-17145.

It is preferable to use an organic base, such as a tertiary amine, a piperidine, a piperazine, an amidine, a formamidine, a pyridine, a guanidine, a morpholine, or the like, in order to accelerate the coupling reaction between the diazo compound and the coupler.

Specific examples of the organic base include piperazines such as N,N′-bis(3-phenoxy-2-hydroxypropyl)piperazine, N,N′-bis[3-(p-methylphenoxy)-2-hydroxypropyl]piperazine, N,N′-bis[3-(p-methoxyphenoxy)-2-hydroxypropyl]piperazine, N,N′-bis(3-phenylthio-2-hydroxypropyl)piperazine, N,N′-bis[3-(β-naphthoxy)-2-hydroxypropyl]piperazine, N-3-(β-naphthoxy)-2-hydroxypropyl-N′-methylpiperazine, 1,4-bis{[3-(N-methylpiperazino)-2-hydroxy]propyloxy}benzene and the like; morpholines such as N-[3-(β-naphthoxy)-2-hydroxy]propylmorpholine, 1,4-bis[(3-morpholino-2-hydroxy)propyloxy]benzene, and 1,3-bis[(3-morpholino-2-hydroxy)propyloxy]benzene and the like; piperidines such as N-(3-phenoxy-2-hydroxypropyl)piperidine, N-dodecylpiperidine and the like; triphenylguanidine, tricyclohexylguanidine, dicyclohexylguanidine, 4-hydroxybenzoic acid 2-N-methyl-N-benzylaminoethyl ester, 4-hydroxybenzoic acid 2-N,N-di-n-butylaminoethyl ester, 4-(3-N,N-dibutylaminopropoxy)benzenesulfonamide, 4-(2-N,N-dibutylaminoethoxycarbonyl)phenoxyacetic acid amide, and so on.

These organic bases may be used singly or in a combination of two or more kinds.

These organic bases are described in, for example, JP-A Nos. 57-123086, 60-49991, and 60-94381, and Japanese Patent Application Nos. 7-228731, 7-235157, and 7-235158, and the like.

If the organic base is to be used, an organic base having a polymerizable group may be used as the organic base.

If an organic base having a polymerizable group is used in the recording material according to the first mode, it is possible to enclose both the diazo compound and the coupler in the microcapsules, to serve as color-forming components A, so that the organic base having a polymerizable group functions as the color-forming component B. If the diazo compound and the coupler are to be enclosed in microcapsules to serve as the color-forming components A, the diazo compound and the coupler are used in a combination in which a color-forming reaction does not occur without the presence of a base.

In addition, in the recording material according to the first mode, it is also possible to use the diazo compound as the color-forming component A and to use a combination of the coupler having a polymerizable group and the organic base having a polymerizable group as the color-forming component B.

The amount to be used of the organic base is not particularly limited, but it is preferable to use the organic base in an amount falling in a range of 1 to 30 moles for 1 mole of the diazo compound.

A color development aid can be added in order to accelerate the color-forming reaction. Examples of the color development aid include a phenol derivative, a naphthol derivative, an alkoxy-substituted benzene, an alkoxy-substituted naphthalene, a hydroxy compound, a carboxylic acid amide, a sulfonamide compound, and so on.

Next, polymerizable compounds that are used in the recording material according to the second mode are explained below.

In the recording material according to the second mode, the recording layer thereof contains, as a polymerizable compound, a color formation-inhibiting compound (this compound is hereinafter referred to as “a polymerizable color formation-inhibiting compound” upon occasion) having in the molecule thereof a site that inhibits the reaction between the color-forming component A and the color-forming component B, which reacts with the color-forming component A and causes the color-forming component A to develop color, and an ethylenically unsaturated bond.

If an electron-donating dye precursor is used as the color-forming component A and an electron-accepting compound having no polymerizable group is used as the color-forming component B, it is preferable to use as the polymerizable, color formation-inhibiting compound a photopolymerizable monomer (hereinafter referred to as “photopolymerizable monomer D₁” upon occasion) having in the molecule thereof a site, which inhibits the reaction between the electron-donating dye precursor and the electron-accepting compound, and at least one vinyl group.

Specific examples of the photopolymerizable monomer D₁ include acrylic acid and salts thereof, acrylic esters, and acrylamides; methacrylic acid and salts thereof, methacrylic esters, and methacrylamides; maleic anhydride and maleates; itaconic acid and itaconates; styrenes; vinyl ethers; vinyl esters; N-vinyl heterocycles; allyl ethers and allyl esters, and so on.

Among these monomers, compounds having in the molecule thereof a plurality of vinyl groups are preferable. Specifically, acrylic or methacrylic esters of polyhydric alcohols such as trimethylolpropane and pentaerythritol and the like; acrylic or methacrylic esters of polyhydric phenols and bisphenols, such as resorcinol, pyrogallol, and phloroglucinol,; acrylate- or methacrylate-endstopped epoxy resins; acrylate- or methacrylate-endstopped polyesters, and the like are preferable.

Among these compounds, particularly preferable are ethylene glycol diacrylate, ethylene glycol dimethacrylate, trimethylolpropane triacrylate, pentaerythritol tetraacrylate, dipentaerythritol hydroxypentaacrylate, hexanediol-1,6-dimethacrylate, and diethylene glycol dimethacrylate and the like.

The molecular weight of the photopolymerizable monomer D₁ is preferably about 100 to about 5000, and more preferably about 300 to about 2000.

If the photopolymerizable monomer D₁ is used as the polymerizable color formation-inhibiting compound, the amount to be used is preferably 0.1 to 10 parts by weight, more preferably 0.5 to 5 parts by weight, for 1 part by weight of the electron-donating compound to be used in combination with the coupler compound having no polymerizable group. If the amount is less than 0.1 part by weight, a latent image may not be formed in an exposing step, and if the amount exceeds 10 parts by weight, the density of developed color may drop.

If a diazo compound is used as the color-forming component A and a coupler compound having no polymerizable group is used as the color-forming component B, it is preferable to use as the polymerizable color formation-inhibiting compound a photopolymerizable monomer (hereinafter referred to as “a photopolymerizable monomer D₂″ upon occasion) having in the molecule thereof an acidic group that inhibits the coupling reaction between the diazo compound, and the coupler compound and at least one vinyl group.

Suitable examples of the photopolymerizable monomer D₂ include styrenesulfonylaminosalicylic acid, vinylbenzyloxyphthalic acid, zinc β-methacryloxyethoxysalicylate, zinc β-acryloxyethoxysalicylate, vinyloxyethyl oxybenzoate, β-methacryloxyethyl orsellinate, β-acryloxyethyl orsellinate, β-methacryloxyethoxyphenol, β-acryloxyethoxyphenol, β-methacryloxyethyl-β-resorcinate, β-acryloxyethyl-β-resorcinate, hydroxystyrenesulfonic acid-N-ethylamide, β-methacryloxypropyl-p-hydroxybenzoate, β-acryloxypropyl-p-hydroxybenzoate, methacryloxymethylphenol, acryloxymethylphenol, methacrylamidepropanesulfonic acid, acrylamidepropanesulfonic acid, β-methacryloxyethoxy-dihydroxybenzene, β-acryloxyethoxy-dihydroxybenzene, γ-styrenesulfonyloxy-α-methacryloxypropanecarboxylic acid, γ-acryloxypropyl-α-hydroxyethyloxysalicylic acid, β-hydroxyethoxyphenol, β-methacryloxyethyl-p-hydroxycinnamate, β-acryloxyethyl-p-hydroxycinnamate, 3,5-distyrenesulfonamidephenol, methacryloxyethoxyphthalic acid, acryloxyethoxyphthalic acid, methacrylic acid, acrylic acid, methacryloxyethoxyhydroxynaphthoic acid, acryloxyethoxyhydroxynaphthoic acid, 3-β-hydroxyethoxyphenol, β-methacryloxyethyl-p-hydroxybenzoate, β-acryloxyethyl-p-hydroxybenzoate, β-methacryloxyethyl-β-resorcinate, β-methacryloxyethyloxycarbonylhydroxybenzoic acid, β-acryloxyethyloxycarbonylhydroxybenzoic acid, N,N-di-β-methacryloxyethylaminosalicylic acid, N,N-di-β-acryloxyethylaminosalicylic acid, N,N-di-β-methacryloxyethylaminosulfonylsalicylic acid, N,N-di-β-acryloxyethylaminosulfonylsalicylic acid, and so on.

When the photopolymerizable monomer D₂ is used as the polymerizable color formation-inhibiting compound, the amount to be used is preferably 0.1 to 10 parts by weight, more preferably 0.5 to 5 parts by weight, for 1 part by weight of the coupler compound to be used in combination with the coupler compound having no polymerizable group. If the amount is less than 0.1 part by weight, a latent image may not be formed in the exposing step, and if the amount exceeds 10 parts by weight, the density of developed color may drop.

(Microcapsules)

In the recording material of the present invention, the recording layer preferably contains the color-forming component A in a state encapsulated in microcapsules.

For encapsulation, a conventionally known method can be employed. Examples of methods include a method utilizing coacervation of a hydrophilic wall-forming material described in U.S. Pat. Nos. 2,800,457 and 2,800,458; an interfacial polymerization method described in U.S. Pat. No. 3,287,154, U.K. Patent No. 990,443, and JP-B Nos. 38-19574, 42-446, and 42-771; a method utilizing polymer deposition described in U.S. Pat. Nos. 3,418,250 and 3,660,304; a method utilizing an isocyanate-polyol wall forming material described in U.S. Pat. No. 3,796,669; a method utilizing an isocyanate wall forming material described in U.S. Pat. No. 3,914,511; a method utilizing urea-formaldehyde and urea-formaldehyde-resorcinol wall-forming materials described in U.S. Pat. Nos. 4,001,140, 4,087,376, and 4,089,802; a method utilizing wall-forming materials such as melamine-formaldehyde resin and hydroxypropylcellulose described in U.S. Pat. No. 4,025,455; an in-situ method utilizing polymerization of monomers described in JP-B No. 36-9168 and JP-A No. 51-9079; a method utilizing electrolytic dispersion cooling described in U.K. Patent Nos. 952,807 and 965,074; a spray-drying method described in U.S. Pat. No. 3,111,407 and U.K. Patent No. 930,442; and the like.

The encapsulating method is not limited to the methods listed above. However, it is particularly preferable to employ an interfacial polymerization method of mixing an oil phase, prepared by dissolving or dispersing the color-forming component A in a hydrophobic organic solvent that is to be the core of the capsules, with an aqueous phase having a water-soluble polymer dissolved therein, emulsifying this mixture by means of a homogenizer or the like, and heating this emulsion so as to cause a polymer-forming reaction at droplet surfaces so that polymeric microcapsule walls are formed. This method makes it possible to form capsules having uniform particle diameters in a short period of time and to obtain a recording material excellent in storability as a raw recording material.

Reactants that form a microcapsule wall polymer are added inside and/or outside the droplets. Specific exmples of the microcapsule wall polymer include polyurethane, polyurea, polyamide, polyester, polycarbonate, urea/formaldehyde resin, melamine resin, polystyrene, styrene/methacrylate copolymers, styrene/acrylate copolymers, and soon. Among these substances, polyurethane, polyurea, polyamide, polyester, and polycarbonate are preferable, and polyurethane and polyurea are particularly preferable. The above-listed polymeric substances may be used in a combination of two or more kinds.

Examples of the water-soluble polymer include gelatin, polyvinyl pyrrolidone, polyvinyl alcohol, and so on. For example, If polyurethane is used as a capsule wall material, the microcapsule wall can be formed by mixing a polyvalent isocyanate and a second substance (e.g., polyol or polyamine) that reacts therewith to form the capsule wall in an aqueous solution of the water-soluble polymer (i.e., the aqueous phase) or in an oily medium to be encapsulated (the oil phase), emulsifying the mixture, and heating the resulting emulsion so as to cause the polymer-forming reaction at droplet surfaces.

As the polyvalent isocyanate and the polyol or polyamine with which the polyvalent isocyanate reacts, those that are described in U.S. Pat. Nos. 3,281,383, 3,773,695, and 3,793,268, and JP-B Nos. 48-40347 and 49-24159, and JP-A Nos. 48-80191 and 48-84086 can be used.

When microcapsules containing the color-forming component A are prepared, the color-forming component A to be enclosed in the microcapsules may be present in a state of solution or may be present in a solid state inside the microcapsules.

When enclosing the color-forming component A in a state of solution inside the microcapsules, the color-forming component A which is dissolved in a hydrophobic solution and encapsulated. The amount to be used of the organic solvent is preferably 1 to 500 parts by weight for 100 parts by weight of the color-forming component A.

Commonly used examples of the hydrophobic organic solvent include phosphates, phthalates, acrylates, methacrylates, other carboxylates, fatty acid amides, alkylated biphenyls, alkylated terphenyls, chlorinated paraffin, alkylated naphthalene, diallyl ethane, compounds that are solid at room temperature, oligomer oil, polymer oil, and so on. Specific examples of the organic solvent include the organic solvents described in JP-A Nos. 59-178451 to 59-178455, 59-178457, 60-242094, 63-85633, 6-194825,7-13310 to 7-13311, and 9-106039, and Japanese Patent Application No. 62-75409.

If the color-forming component A to be encapsulated has poor solubility in the organic solvent, a low-boiling-point solvent having high solvency may be used as an auxiliary solvent. Examples of the low-boiling-point solvent include ethyl acetate, propyl acetate, isopropyl acetate, butyl acetate, methylene chloride, and so on.

An aqueous solution having the water-soluble polymer dissolved therein is used as the aqueous phase. The oil phase described above is added to the aqueous phase and thereafter the mixture is emulsified by means of a homogenizer or the like. The water-soluble polymer acts as a dispersing medium which enables uniform and easy dispersion, and stabilizes the aqueous dispersion thus obtained. In this case, in order to obtain a more uniform and stable dispersion, a surfactant may be added to at least one of the oil phase and the aqueous phase. As the surfactant, a conventionally known surfactant for emulsification may be used. When the surfactant is added, the amount of the surfactant to be added is preferably 0.1 to 5% by weight, particularly preferably 0.5 to 2% by weight, based on the weight of the oil phase.

When the color-forming component A is encapsulated, the average particle diameter of the microcapsules is preferably 20 μm or less, and more preferably 5 μm or less, from the standpoint of obtaining high resolution. If the microcapsules formed are too small, a larger amount of wall-forming agents is required because the surface area per amount of the solid components becomes larger. Therefore, the average particle diameter of the microcapsules is preferably 0.1 μm or greater.

Besides the recording material of the present invention described above, the photopolymerizable composition of the present invention can be used in a broad range of application fields including inks, color filters, holograms, proofs, sealants, adhesives, planographic printing, resin relief plates, photoresists and the like. In accordance with the application, other components may be added. Further, when the photopolymerizable composition of the present invention is used in an application other than the recording material of the present invention, the polymerizable compound (3) does not need to function as the color-forming component B color formation-inhibiting compound, and therefore a wide range of polymerizable compounds having an ethylenically unsaturated bond can be used.

A multicolor recording material can be formed by laminating a plurality of single-color recording layers on a support, wherein each recording layer contains a color-forming component A (which may be enclosed in microcapsules) designed to develop a different color, a color-forming component B (which may have a polymerizable group) having in the molecule thereof a site which reacts with the color-forming component A and causes the color-forming component A to develop color, and a photopolymerizable composition which is sensitized by a different wavelength of light to form a latent image. That is, it is possible to obtain photopolymerizable compositions sensitive to different wavelengths of light by incorporating spectral sensitizing dyes each having a different absorption wavelength into the photopolymerizable compositions. In this case, interlayers can be formed between the single-color recording layers.

The multicolor recording material of the present invention can be formed, for example, in the following way.

A multilayer recording layer a having a multilayer structure is produced by disposing on a support a first recording layer which contains microcapsules enclosing a yellow color-forming component A^{Y}, a color-forming component B^{Y} that causes the color-forming component A^{Y} to develop color, and a photopolymerizable composition sensitive to light having a central wavelength of λ₁ so as to form a latent image; disposing on the first recording layer a second recording layer which contains microcapsules enclosing a magenta color-forming component A^{M}, a color-forming component B^{M} that causes the color-forming component A^{M} to develop color, and a photopolymerizable composition sensitive to light having a central wavelength of λ₂ so as to form a latent image; and disposing on the second recording layer a third recording layer which contains microcapsules enclosing a cyan color-forming component A^{C}, a color-forming component Bc that causes the color-forming component A^{C} to develop color, and a photopolymerizable composition sensitive to light having a central wavelength of λ₃ so as to form a latent image. If necessary, the multicolor recording material of the present invention may be comprised of a multilayer recording layer β, which has interlayers formed between layers of the multilayer recording layer α, or the like.

In a case where image formation is carried out using the recording material having the multicolor, multilayer recording layer described above, in an image-wise exposure step, exposure is performed with a plurality of light sources having different wavelengths suited to the respective absorption wavelengths of the recording layers. This exposure enables the recording layers, whose absorption wavelengths match the respective wavelengths of the light sources, to form images selectively. Therefore, multicolor images can be formed with high sensitivity and sharpness. Furthermore, when the entire face of the recording layer is irradiated with light, the background coloration due to, photopolymerizable composition remaining in the layer such as spectral sensitizing dyes, can be decolorized. As a result, high-quality, multicolor images with high contrast can be formed.

(Support)

Any of paper supports for ordinary pressure-sensitive paper, heat-sensitive paper, or dry-process or wet-process diazo copying paper can be used as the support. In addition, acidic paper, neutral paper, coated paper, plastic film-laminated paper, synthetic paper, plastic film, or the like can be used.

The recording material of the present invention can be suitably used in such applications as planographic printing, resin relief plates, photoresists or photomasks for preparation of a substrate of a printed circuit, black-and-white or colored transfer coloration sheets, and color-forming sheets. For example, when the recording material of the present invention is used for preparation of a photo- and heat-sensitive color-forming sheet, processes include dissolving or dispersing the components singly or in a combination of several kinds thereof in a suitable solvent to thereby prepare a solution or a dispersion liquid, preparing a coating liquid by blending the solution or dispersion liquid, applying the coating liquid onto a support such as a paper or a plastic film, and drying the coating layer. For example, when a specific component is to be encapsulated, a coating liquid can be prepared by preparing a dispersion liquid containing microcapsules that enclose the component, and blending the dispersion liquid with a liquid separately prepared by dissolving or dispersing other components in a solvent. In the preparation of the coating liquid, the components can be transformed into a desirable dispersed state by use of a homogenizer or the like.

As a method for coating and drying, conventionally known methods can be employed.

With the recording material of the present invention, image formation can be carried out by heat development simultaneously with exposure for the formation of a latent image, or after the exposure.

As a method of heating for carrying out heat development, conventionally known methods can be employed. Generally, the heating temperature is preferably 80 to 200° C. and more preferably 85 to 130° C. The heating time is preferably from 1 second to 5 minutes and more preferably from 3 seconds to 1 minute.

After heat development, it is preferable to irradiate the entire face of the recording layer with light so that the images formed are fixed by polymerization in portions that have not yet undergone polymerization and components that remain in the recording layer can and impair whiteness of the background, for example, a spectral sensitizing dye, are decolorized or deactivated.

In the recording material of the present invention, color retention of the background can be prevented and the whiteness of the background can be enhanced by a shorter image-fixing treatment in comparison with conventional recording materials.

In the image formation according to the method described above, the sensitivity can be further enhanced by providing in the process of the image formation a step in which the entire face of the material is uniformly preheated to a predetermined temperature that is lower than the color-forming temperature. Use of the recording material of the present invention is not limited to the recording method described above and the recording material of the present invention can be used for other recording methods.

As stated above, the recording material of the present invention enables image recording with a high sensitivity by use not only of ultraviolet light but also of visible-to-infrared light in a perfectly dry system requiring no developing solution and producing no waste and enables excellent decolorization in non-image portions (background) and the formation of sharp, high-contrast black and white or color images.

### EXAMPLES

Examples of the present invention will be explained below. However, it should be noted that the present invention is not limited to these Examples. In the following Examples, “%” means “% by weight” and “parts” means “part by weight” unless otherwise specified.

Organic dyes (i.e., the compounds represented by the general formulae (1) to (3)) in the Examples were synthesized in accordance with the synthesis methods described previously.

### Examples 1 to 10

Photopolymerizable compositions with the following formulations were prepared using exemplary organic dyes (i.e., compounds represented by the general formulae (1) to (3); spectral sensitizing dyes) and the organoboron compounds listed in Table 1.

[Photopolymerizable compositions]

| | |
|---|---|
| pentaerythritol tetraacrylate | 1.41 g |
| benzyl methacrylate/methacrylic acid copolymer (at a | 1.29 g |
| molar ratio of 73/27) | |
| methyl ethyl ketone | 12 g |
| propylene glycol monomethyl ether acetate | 8.62 g |
| organic dye (exemplary compound; see Table 1) | 1 × 10⁻⁴ mole |
| organoboron compound indicated below (see Table 1) | 6 × 10⁻⁴ mole |
| methanol | 6 g |

The structures of borates (1) and (2) in following Table 1 are shown below.

[chemical structure]

Each of the photopolymerizable compositions thus prepared was applied at a thickness of 2 μm onto a polyethylene terephthalate film having a thickness of 100 μm and thereafter dried at 100° C. for 5 minutes. Further, the following coating liquid (1) for a protective layer was applied at a thickness of 1 μm onto the layer described above and thereafter dried at 100° C. for 2 minutes. In this way, photosensitive materials (1) to (10) of the present invention were prepared.

[Coating liquid (1) for protective layer]

| | |
|---|---|
| water | 98 g |
| polyvinyl alcohol | 1.7 g |
| hydroxypropylolmethyl cellulose | 1.7 g |
| polyvinyl pyrrolidone | 8.7 g |

### Comparative Examples 1 and 2

Photosensitive materials (11) and (12) were prepared by the same procedure as in Example 1, except that the organic dye (exemplary compound No.2) in Example 1 was replaced with an organic dye (spectral sensitizing dye) d-1 or d-2 shown below.

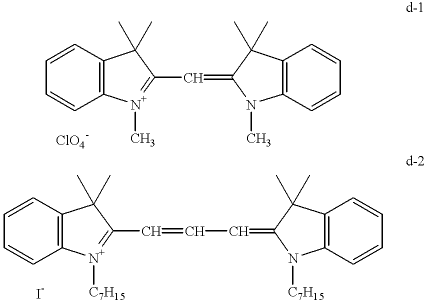

<Image Formation and Assessment>

The photosensitive materials (1) to (10) of the present invention and the photosensitive materials (11) and (12) of Comparative Examples 1 and 2 thus prepared were exposed to light using a vacuum printing frame. Exposure was carried out by irradiating the photosensitive materials with light from a 500 W xenon lamp (manufactured by Ushio Co., Ltd.) for 10 seconds through a step wedge (having density difference in steps of 0.15 for density steps 1 to 15, “FUJI STEPGUIDE P” (manufactured by Fuji Photo film Co., Ltd.) and an “SC 38 FILTER” (manufactured by Fuji Photo film Co., Ltd., a sharp cut filter eliminating light having wavelengths of 380 nm or less). After exposure, the photosensitive materials were subjected to development processing using a developing solution having the following composition.

[Developing Solution]

| | |
|---|---|
| Anhydrous sodium carbonate | 10 g |
| Butyl cellosolve | 5 g |
| Water | 11 g |

Since exposure amounts to regions corresponding to higher step numbers of the step wedge were small, the photopolymerizable composition in these regions was dissolved in the developing solution in the development processing and the surface of the polyethylene terephthalate (PET) emerged. For the photosensitive materials of the Examples, a region where the photopolymerizable composition was completely dissolved was examined, and the step number of a step wedge corresponding to the region of the largest exposure amount (clear step number) was sought. The higher the step number, the higher the sensitivity of the photosensitive material. The results are shown in Table 1.

In a case where the photopolymerizable composition was dissolved in the developing solution throughout the entire exposed region, because of low sensitivity, the assessment result of the photopolymerizable composition is shown as “flowed”.

On the other hand, after the photosensitive materials (1) to (10) of the present invention and the photosensitive materials (11) and (12) of the Comparative Examples thus prepared were exposed to light from a fluorescent lamp (30000 lux) for 10 minutes, yellow, magenta, and cyan densities were measured using a transmission Macbeth densitometer. The better decolorization the exposure of the organic dye compounds contained, the lower a fogging density of the background was. The results are shown in Table 1.

In Table 1, the figures (Nos.) in the organic dye column correspond to number of exemplary compounds represented by the general formulae (1) to (3). The same applies in Table 2 following.

TABLE 1

| | | | | maximum | | fogging density | | |
|---|---|---|---|---|---|---|---|---|
| | photosensitive | | Organoboron | wavelength | Clear step | after exposure | | |
| | material | organic dy | compound | (nm) | number | yellow | magenta | cyan |
| Example | (1) | No. 2 | borate 1 | 446 | 6 | 0.07 | 0.05 | 0.05 |
| 1 | | | | | | | | |
| Example | (2) | No. 3 | borate 1 | 560 | 6 | 0.06 | 0.06 | 0.05 |
| 2 | | | | | | | | |
| Example | (3) | No. 7 | borate 1 | 560 | 10 | 0.05 | 0.05 | 0.05 |
| 3 | | | | | | | | |
| Example | (4) | No. 8 | borate 1 | 560 | 11 | 0.05 | 0.05 | 0.05 |
| 4 | | | | | | | | |
| Example | (5) | No. 10 | borate 1 | 560 | 10 | 0.05 | 0.05 | 0.05 |
| 5 | | | | | | | | |
| Example | (6) | No. 19 | borate 2 | 655 | 8 | 0.06 | 0.05 | 0.06 |
| 6 | | | | | | | | |
| Example | (7) | No. 21 | borate 2 | 662 | 10 | 0.05 | 0.05 | 0.05 |
| 7 | | | | | | | | |
| Example | (8) | No. 23 | borate 2 | 571 | 7 | 0.06 | 0.06 | 0.05 |
| 8 | | | | | | | | |
| Example | (9) | No. 25 | borate 2 | 573 | 8 | 0.05 | 0.05 | 0.05 |
| 9 | | | | | | | | |
| Example | (10) | No. 27 | borate 2 | 495 | 8 | 0.05 | 0.05 | 0.05 |
| 10 | | | | | | | | |
| Compara- | (11) | d-1 | borate 1 | 440 | Flowed | 0.4 | 0.05 | 0.05 |
| tive | | | | | | | | |
| example | | | | | | | | |
| 1 | | | | | | | | |
| Compara- | (12) | d-2 | borate 1 | 560 | 4 | 0.05 | 0.25 | 0.05 |
| tive | | | | | | | | |
| example | | | | | | | | |
| 2 | | | | | | | | |

From the results shown in Table 1, it was found that the photosensitive materials (1) to (10) of the present invention, which used the compounds represented by the general formulae (1) to (3) as organic dyes, had better sensitivity and were so excellent in decolorization that images free from remaining color due to dye components could be formed.

On the other hand, the photosensitive materials (11) and (12) of the Comparative Examples, which did not use the organic dyes specified in the present invention, could not obtain high sensitivity and exhibited inferior decolorization.

### Example 11

<Preparation of a Microcapsule Liquid Composed of Microcapsules Enclosing an Electron-donating Colorless Dye>

(1-a) Preparation of a Microcapsule Liquid Composed of Microcapsules Enclosing an Electron-donating Colorless Dye (1)

8.9 g of the electron-donating colorless dye (1) indicated below was dissolved in 16.9 g of ethyl acetate. To this solution were added 20 g of “TAKENATE D-110N” (manufactured by Takeda Chemical Industries, Ltd.) and 2 g of “MILLIONATE MR 200” (manufactured by Nippon Polyurethane Industries, Ltd.) as encapsulants. The resulting solution was added to a mixture of 42 g of a 8% solution of phthalated gelatin and 1.4 g of a 10% solution of sodium dodecylbenzenesulfonate. The resulting mixture was emulsified at 20° C. and an emulsion was obtained. To the emulsion thus obtained were added 14 g of water and 72 g of a 2.9% tetraethylenepentamine aqueous solution. After that, while being stirred, this mixture was heated to 60° C. and was kept at that temperature for 2 hours. In this way, a microcapsule liquid composed of microcapsules enclosing the electron-donating colorless dye (1) as the core and having an average particle diameter of 0.5 μm was obtained.

Electron-donating colorless dye (1)

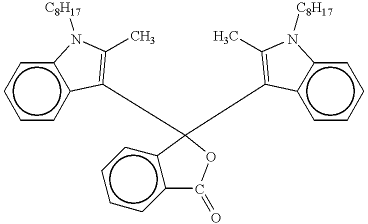

<Preparation of an Emulsion of a Photopolymerizable Composition>

(2-a) Preparation of an Emulsion of a Photopolymerizable Composition

5.3 g of isopropyl acetate was added to 0.05 g of an organic dye (exemplary compound No.2, see the following Table 2), 0.3 g of borate (1) (organoboron compound), 0.05 g of the following polymerization aid, and 4.2 g of the following polymerizable electron-accepting compound (1), and this mixture was stirred to obtain a solution by dissolution.

Polymerization Aid (1)

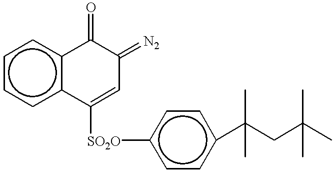

Polymerizable Electron-accepting Compound (1)

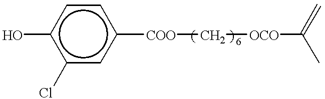

This solution was added to a mixture of 13 g of an 8% gelatin aqueous solution, 0.8 g of a 2% aqueous solution of the following surfactant (1), and 0.8 g of a 2% aqueous solution of the following surfactant (2). The resulting mixture was emulsified at 10000 rpm for 5 minutes by means of a homogenizer (manufactured by Nippon seiki Co., Ltd.), and an emulsion of the photopolymerizable composition was obtained.

Surfactant (1)

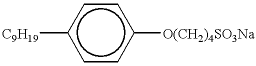

Surfactant (2)

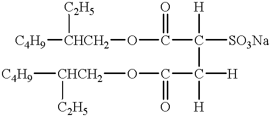

<Preparation of Coating Liquid for Recording Layer>

(3-a) Preparation of Coating Liquid for Recording Layer

A coating liquid for a recording layer was prepared by mixing 4 g of the microcapsule liquid composed of microcapsules enclosing electron-donating colorless dye (1), 12 g of the emulsion of the photopolymerizable composition, and 12 g of a 15% gelatin aqueous solution.

<Preparation of Coating Liquid (2) for Protective Layer>

(4-a) Preparation of Coating Liquid (2) for Protective Layer

A coating liquid (2) for a protective layer was prepared by mixing 4.5 g of a 10% gelatin aqueous solution, 4.5 g of distilled water, 0.5 g of a 2% aqueous solution of the following surfactant (3), 0.3 g of a 2% aqueous solution of the following surfactant (4), 0.5 g of a 2% aqueous solution of the following hardening agent (1), “SYLOID 72” (manufactured by FUJI-DEVISON CHEMICAL LTD.) in an amount providing a coating weight of 50 mg/m², and 1 g of “SNOWTEX N”.

Surfactant (3)

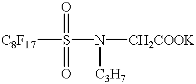

Surfactant (4)

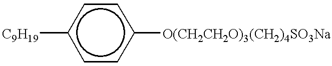

Hardening Agent (1)

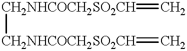

<Support>

A white Polyester film filled with a white Pigment and having a thickness of 100 μm (“LUMILAR-E68L” manufactured by Toray Industries, Inc.) was used as a support. Using a coating bar, the coating liquid for the recording layer was applied onto the support such that the dry weight of the coating layer would be 6 g/m², and the layer was dried at 30° C. for 10 minutes. Onto the recording layer was applied, using a coating bar, the coating liquid (2) for the protective layer such that the dry weight of the coating layer would be 2 g/m², and the protective layer was dried at 30° C. for 10 minutes. In this way, the photo- and heat-sensitive recording material (a) of the present invention was obtained.

### Examples 12 to 17

Photo- and heat-sensitive recording materials (b) to (g) of the present invention were prepared by the same procedure as in Example 11, except that the organic dye (exemplary compound No.2) and the organoboron compound (borate (1)) of Example 11 were replaced, respectively, with exemplary organic dyes (i.e., compounds represented by the general formulae (1) to (3); spectral sensitizing dyes) and the organoboron compounds according to the following Table

### Comparative Examples 3 and 4

Photo- and heat-sensitive recording materials (h) and (i) were prepared by the same procedure as in Example 11, except that the organic dye (exemplary compound No.2) was replaced with the organic dye d-1 or d-2 as shown in the following Table 2.

<Image Formation and Assessment>

The photo- and heat-sensitive recording materials (a) to (g) of the present invention and the photo- and heat-sensitive recording materials (h) and (i) of the Comparative Examples thus prepared were exposed to light using a vacuum printing frame by irradiating the photo- and heat-sensitive sheets with light of the 500 W xenon lamp for 30 seconds through the step wedge and SC 38 FILTER to thereby form respective latent images. After the exposure, each photo- and heat-sensitive recording material was heated for 15 seconds by means of a hot plate at 125° C. As a result, a magenta color, i.e., the color to be formed by the reaction between the electron-donating colorless dye (1) and the polymerizable electron-accepting compound (1), was formed in unexposed portions, whereas the density of developed color was lower or color formation did not occur in exposed portions. A region where color formation did not occur was examined and the step number of the step wedge corresponding to the region of with smallest exposure amount (clear step number) was sought. The higher the number, the higher the sensitivity of the photo- and heat-sensitive recording material.

The results are shown in Table 2. In the case where color formation occurred at all of the steps because of low sensitivity, the photopolymerizable composition is rated as “solid” in Table 2.

Further, after the photo- and heat-sensitive recording materials were exposed to the light of a fluorescent lamp (30000 lux) for 10 minutes, yellow, magenta, and cyan densities of the background were measured using a transmission Macbeth densitometer. The better decolorization by exposure of the contained organic dyes, the lower a fogging density of the background. The results are shown in Table 2.

TABLE 2

| | photo- and | | | | | | | |
|---|---|---|---|---|---|---|---|---|
| | heat- | | | | | | | |
| | sensitive | | | maximum | | fogging density | | |
| | recording | | Organoboron | wavelength | clear step | after exposure | | |
| | material | organic dye | compound | (nm) | number | yellow | magenta | cyan |
| Example 11 | (a) | No. 2 | borate 1 | 446 | 6 | 0.08 | 0.05 | 0.05 |
| Example 12 | (b) | No. 3 | borate 1 | 560 | 7 | 0.06 | 0.07 | 0.05 |
| Example 13 | (c) | No. 7 | borate 1 | 560 | 11 | 0.05 | 0.06 | 0.05 |
| Example 14 | (d) | No. 8 | borate 1 | 560 | 12 | 0.05 | 0.06 | 0.05 |
| Example 15 | (e) | No. 10 | borate 2 | 560 | 12 | 0.05 | 0.06 | 0.05 |
| Example 16 | (f) | No. 19 | borate 2 | 655 | 9 | 0.06 | 0.05 | 0.06 |
| Example 17 | (g) | No. 21 | borate 2 | 662 | 11 | 0.05 | 0.05 | 0.06 |
| Comparative | (h) | d-1 | borate 1 | 440 | solid | 0.42 | 0.06 | 0.05 |
| example 3 | | | | | | | | |
| Comparative | (i) | d-2 | borate 1 | 560 | 4 | 0.07 | 0.44 | 0.05 |
| example 4 | | | | | | | | |

Based on the results shown in Table 2, it was found that the photo- and heat-sensitive recording materials (a) to (g) of the present invention, which used the compounds represented by the general formulae (1) to (3) as organic dyes, had better sensitivity and excellent decolorization property and could form sharp and high-contrast images.

On the other hand, the photo- and heat-sensitive recording materials (h) and (i) of the Comparative Examples, which did not use the organic dyes specified in the present invention, could not obtain high sensitivity and exhibited inferior decolorization.

With the present invention, it is possible to provide a novel cyanine dye which is highly decomposable by a radical and exhibits excellent decolorization, and a photopolymerizable composition which has a high sensitivity not only to ultraviolet light but also to visible-to-infrared light. It is also possible to provide a recording material which enables image recording with high sensitivity using not only ultraviolet light but also visible-to-infrared light and which can form sharp, high-contrast black and white or color images with excellent decolorization of non-image portions (background) in a perfectly dry system requiring no developing solution and producing no waste.

What is claimed is:

1. A photopolymerizable composition comprising a polymerizable compound having an ethylenically unsaturated bond, a compound represented by following general formula (1), and a radical generator capable of interacting with the compound represented by the general formula (1) and generating a radical: [chemical structure]
Wherein, in the general formula (1):R¹ represents an aliphatic group having a triple bond, and R² represents a hydrogen atom, an aliphatic group, or an aromatic group; L¹, L², and L³ each independently represents a methine group that may have a substituent, and if L¹, L², and L³ each represents a methine group that has a substituent, the substituents may join together to form an unsaturated aliphatic ring or an unsaturated heterocycle; Z¹ and Z² each independently represents an atomic group that forms a 5-membered or 6-membered nitrogen-containing heterocycle, an aromatic ring may be condensed with the nitrogen-containing heterocycle and the nitrogen-containing heterocycle, and the aromatic ring condensed with the nitrogen-containing heterocycle may each have a substituent; n represents 0, 1, 2, or 3; and X⁻ represents a group capable of forming an anion.

2. A photopolymerizable composition according to claim 1, wherein the compound represented by the general formula (1) is a compound represented by following general formula (2): [chemical structure]
in which the general formula (2): R¹¹ represents an aliphatic group having a triple bond, and R¹² represents a hydrogen atom, an aliphatic group, or an aromatic group; L¹¹, L¹², and L¹³ each independently represents a methine group that may have a substituent, and, if L¹¹, L¹², and L¹³ each represents a methine group that has a substituent, the substituents may join together to form an unsaturated aliphatic ring or an unsaturated heterocycle; Y¹¹ and Y¹² each independently represents —CR²⁸R²⁹—, —NR³⁰—, —O—, —S—, or Se—; R²⁸, R²⁹, and R³⁰ each independently represents a hydrogen atom, an aliphatic group, or an aromatic group, and R²⁸ and R²⁹ may each be anatomic, group which atomic groups join together to form a ring; Z¹¹ and Z¹² are benzene rings, with which other benzene rings may be condensed, and the benzene rings Z¹¹ and Z¹² and benzene rings condensed therewith may each have a substituent; n′ represents 0, 1, 2, or 3; and X⁻ represents a group capable of forming an anion.

3. A photopolymerizable composition according to claim 2, wherein the compound represented by the general formula (2) is a compound represented by following general formula (3): [chemical structure]
in which general formula (3) R¹³, R¹⁴, R¹⁵, R¹⁶, R¹⁷, and R¹⁸ each represents a hydrogen atom, an aliphatic group, or an aromatic group; R¹⁹ represents a bivalent aliphatic group; L²¹, L²², and L²³ each independently represents a methine group that may have a substituent, and, if L²¹, L²², and L²³ each represents a methine group that has a substituent, the substituents may join together to form an unsaturated aliphatic ring or an unsaturated heterocycle; Z²¹ and Z²² are benzene rings, with which other benzene rings may be condensed, and the benzene rings Z²¹ and Z²² and benzene rings condensed therewith may each have a substituent; n″ represents 0, 1, 2, or 3; and X⁻ represents a group capable of forming an anion.

4. A photopolymerizable composition according to claim 1, wherein the radical generator is an organoboron compound.

5. A photopolymerizable composition according to claim 3, wherein the radical generator is an organoboron compound.

6. A photopolymerizable composition according to claim 4, wherein the organoboron compound is a compound represented by following general formula (A): [chemical structure]
in which general formula (A), Rₐ¹, Rₐ², Rₐ³, and Rₐ⁴ each independently represents an aliphatic group, an aromatic group, a heterocyclic group, or —Si(Rₐ⁵) (Rₐ⁶)—Rₐ⁷; Rₐ⁵, Rₐ⁶ and Rₐ⁷ each independently represents an aliphatic group or an aromatic group; and G⁺ represents a group capable of forming a cation.

7. A photopolymerizable composition according to claim 5, wherein the organoboron compound is a compound represented by following general formula (A): [chemical structure]
in which general formula (A), Rₐ¹, Rₐ², Rₐ³, and Rₐ⁴ each independently represents an aliphatic group, an aromatic group, a heterocyclic group, or —Si (Rₐ⁵)(Rₐ⁶)—Rₐ⁷; Rₐ⁵, Rₐ⁶ and Rₐ⁷ each independently represents an aliphatic group or an aromatic group; and G⁺ represents a group capable of forming a cation.

8. A recording material comprising a support having thereon a recording layer which contains at least a first color-forming component, a second color-forming component which has a site that reacts with the color-forming component and causes the first color-forming component to develop color, and the photopolymerizable composition according to claim 1.

9. A recording material comprising a support having thereon a recording layer which contains at least a first color-forming component, a second color-forming component which has a site that reacts with the color-forming component and causes the first color-forming component to develop color, and the photopolymerizable composition according to claim 4.

10. A recording material comprising a support having thereon a recording layer which contains at least a first color-forming component, a second color-forming component which has a site that reacts with the color-forming component and causes the first color-forming component to develop color, and the photopolymerizable composition according to claim 6.

11. A recording material according to claim 8, wherein the polymerizable compound having an ethylenically unsaturated bond is the second color-forming component.

12. A recording material according to claim 9,wherein the polymerizable compound having an ethylenically unsaturated bond is the second color-forming component.

13. A recording material according to claim 10, wherein the polymerizable compound having an ethylenically unsaturated bond is the second color-forming component.

14. A recording material according to claim 8, wherein the polymerizable compound having an ethylenically unsaturated bond is a color formation-inhibiting compound having in a molecule thereof a site which inhibits a reaction between the first color-forming component and the second color-forming component.

15. A recording material according to claim 9 wherein the polymerizable compound having an ethylenically unsaturated bond is a color formation-inhibiting compound having in a molecule thereof a site which inhibits a reaction between the first color-forming component and the second color-forming component.

16. A recording material according to claim 10, wherein the polymerizable compound having an ethylenically unsaturated bond is a color formation-inhibiting compound having in a molecule thereof a site which inhibits a reaction between the first color-forming component and the second color-forming component.

17. A recording material according to claim 8, wherein the first color-forming component is enclosed in microcapsules.

18. A recording material according to claim 10, wherein the first color-forming component is enclosed in microcapsules.

19. A recording material according to claim 8, wherein the recording material has a multilayer structure in which a plurality of recording layers are sequentially laminated, each recording layer being sensitive to light having a central wavelength that is different from a central wavelength of light to which any other of the recording layers is sensitive, and each layer developing a color that is different from a color which any other of the recording layers develops.

20. A cyanine-based organic dye represented by the following general formula (3): [chemical structure]
in which general formula (3): R¹³, R¹⁴, R¹⁵, R¹⁶, R¹⁷, and R¹⁸ each represents a hydrogen atom, an aliphatic group, or an aromatic group; R¹⁹ represents a bivalent aliphatic group; L²¹, L²², and L²³ each independently represents a methine group that may have a substituent, and, if L²¹, L²², and L²³ each represents a methine group that has a substituent, the substituents may join together to form an unsaturated aliphatic ring or an unsaturated heterocycle; Z²¹ and Z²² are benzene rings, with which other benzene rings may be condensed, and the benzene rings Z²¹ and Z²² and benzene rings condensed therewith may each have a substituent; n″ represents 0, 1, 2, or 3; and X⁻ represents a group capable of forming an anion.
